(19) United States
(12) Patent Application Publication
(10) Pub. No.: US 2024/0363623 A1
(43) Pub. Date: Oct. 31, 2024

(54) SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Soichi YOSHIDA, Matsumoto-city (JP)

(21) Appl. No.: 18/766,587

(22) Filed: Jul. 8, 2024

Related U.S. Application Data
(63) Continuation-in-part of application No. 18/404,920, filed on Jan. 5, 2024.

(30) Foreign Application Priority Data
Jan. 16, 2023 (JP) 2023-004623
Nov. 14, 2023 (JP) 2023-193814

(51) Int. Cl. H01L 27/06; H01L 29/32; H01L 29/739; H01L 29/861

(52) U.S. Cl. CPC H01L 27/0664; H01L 29/32; H01L 29/7397; H01L 29/8613

(57) ABSTRACT

Provided is a semiconductor device including one or more first mesa portions, each of which is provided with a first lifetime adjustment region and has a first contact portion in contact with an upper electrode, and one or more second mesa portions, each of which is not provided with the first lifetime adjustment region and has a second contact portion in contact with the upper electrode, and a first depth position of the first contact portion of at least one of the one or more first mesa portions is provided at a position deeper than a second depth position of the second contact portion of at least one of the one or more second mesa portions with respect to an upper surface of a semiconductor substrate.

The contents of the following patent application(s) are incorporated herein by reference:
NO. 2023-004623 filed in JP on Jan. 16, 2023
NO. 2023-193814 filed in JP on Nov. 14, 2023
Ser. No. 18/404,920 filed in US on Jan. 5, 2024

### BACKGROUND

### 1. Technical Field

The present invention relates to a semiconductor device.

### 2. Related Art

A structure in which charged particles such as helium are implanted into a semiconductor substrate to form a lifetime adjustment region is known (see, for example, Patent Documents 1 and 2).
Patent Document 1: International Publication No. 2020/162012
Patent Document 2: International Publication No. 2019/013286

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3A illustrates a view showing an example of a cross section e-e in FIG. 2.

FIG. 3B shows a concentration distribution, a net doping concentration distribution, and a carrier lifetime distribution of a recombination center in a first lifetime adjustment region 201 in a Z axis direction along a cross section m-m of FIG. 3A.

FIG. 3C shows another example of the concentration distribution, the net doping concentration distribution, and the carrier lifetime distribution of the recombination center in the Z axis direction in the first lifetime adjustment region 201 along the cross section m-m of FIG. 3A.

FIG. 4A illustrates a view showing an example of a cross section f-f in FIG. 2.

FIG. 4B illustrates an enlarged view of a periphery of a trench contact portion 17.

FIG. 4C illustrates an enlarged view of a periphery of a second contact portion 212.

FIG. 5A illustrates a view showing an arrangement example of the first lifetime adjustment region 201 in a top view.

FIG. 5B illustrates a modification of the arrangement of the first lifetime adjustment region 201 in the top view.

FIG. 5C illustrates a modification of the arrangement of the first lifetime adjustment region 201 in the top view.

FIG. 5D illustrates a modification of the arrangement of the first lifetime adjustment region 201 in the top view.

FIG. 5E illustrates a view showing another arrangement example of the first lifetime adjustment region 201 in the top view.

FIG. 6 illustrates a view showing another example of the cross section f-f in FIG. 2.

FIG. 7 illustrates a view showing another arrangement example of the first lifetime adjustment region 201 in the top view.

FIG. 8 illustrates a view showing another example of the cross section f-f in FIG. 2.

FIG. 9 illustrates a view showing another example of the cross section f-f in FIG. 2.

FIG. 10 illustrates a view showing another example of the cross section f-f in FIG. 2.

FIG. 11 illustrates a view showing an arrangement example of a second lifetime adjustment region 202 in the top view.

FIG. 12 illustrates a view showing another example of the cross section f-f in FIG. 2.

FIG. 13 illustrates a view showing an arrangement example of a third lifetime adjustment region 203 in the top view.

FIG. 14 illustrates a view showing another example of a mesa portion 61 of a diode portion 80.

FIG. 15 illustrates a view showing a structure example of a lower surface 23 of a semiconductor substrate 10.

FIG. 16A illustrates a view showing a structure example of the lower surface 23 of the semiconductor substrate 10.

FIG. 16B illustrates a view showing another structure example of the lower surface 23 of the semiconductor substrate 10.

FIG. 17 illustrates another view showing another example of the mesa portion 61 of the diode portion 80.

FIG. 18 illustrates a view showing another example of the cross section f-f in FIG. 2.

FIG. 19 illustrates a view showing an arrangement example of a first lifetime adjustment region 201-1 and a first lifetime adjustment region 201-3 in the top view.

FIG. 20A illustrates a view showing another example of the cross section f-f in FIG. 2.

FIG. 20B illustrates a view showing an arrangement example of the first lifetime adjustment region 201-1 and the first lifetime adjustment region 201-3 in the top view.

FIG. 21A illustrates a view showing another example of the cross section f-f in FIG. 2.

FIG. 21B illustrates a view showing an arrangement example of the first lifetime adjustment region 201-1 and the first lifetime adjustment region 201-3 in the top view.

FIG. 22A illustrates a view showing another example of the cross section e-e in FIG. 2.

FIG. 22B illustrates a view showing another example of the cross section f-f in FIG. 2.

FIG. 23A illustrates a view showing another example of the cross section f-f in FIG. 2.

FIG. 23B illustrates a view showing another example of the cross section f-f in FIG. 2.

FIG. 23C illustrates a view showing another example of the cross section f-f in FIG. 2.

FIG. 23D illustrates a view showing another example of the cross section f-f in FIG. 2.

FIG. 23E illustrates a view showing another example of the cross section f-f in FIG. 2.

FIG. 23F illustrates another view showing another example of the mesa portion 61 of the diode portion 80.

FIG. 23G illustrates a view showing another example of the cross section f-f in FIG. 2.

FIG. 23H illustrates a view showing another example of the cross section f-f in FIG. 2.

FIG. 23I illustrates a view showing another example of the cross section f-f in FIG. 2.

FIG. 24A illustrates a view showing another example of the cross section f-f in FIG. 2.

FIG. 24B illustrates a view showing another example of the cross section f-f in FIG. 2.

FIG. 24C illustrates a view showing another example of the cross section f-f in FIG. 2.

FIG. 24D illustrates a view showing another example of the cross section f-f in FIG. 2.

FIG. 25 illustrates a view showing another example of the cross section f-f in FIG. 2.

FIG. 26 illustrates a view showing another example of the cross section f-f in FIG. 2.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. The hydrogen donor may be a donor obtained by the combination of at least a vacancy (V) and hydrogen (H). Alternatively, interstitial Si—H in which interstitial silicon (Si-i) in a silicon semiconductor and hydrogen are combined also functions as a donor for supplying electrons. In the present specification, the VOH defect or the interstitial Si—H may be referred to as a hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but is not limited thereto. The bulk donor of this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any of a Czochralski method (CZ method), a magnetic-field applied Czochralski method (MCZ method), and a float zone method (FZ method). The ingot of this example is manufactured by the MCZ method. The concentration of oxygen contained in the substrate manufactured by the MCZ method is 1×10⁷ to 7×10¹⁷/cm³. The concentration of oxygen contained in the substrate manufactured by the FZ method is 1×10⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (D0) of the non-doped substrate is, for example, from 1×10¹⁰/cm³ or more and to 5×10¹¹/cm³ or less. The bulk donor concentration (D0) of the non-doped substrate is preferably 1×10¹¹/cm³ or more. The bulk donor concentration (D0) of the non-doped substrate is preferably 5×10¹¹/cm³ or less. Each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

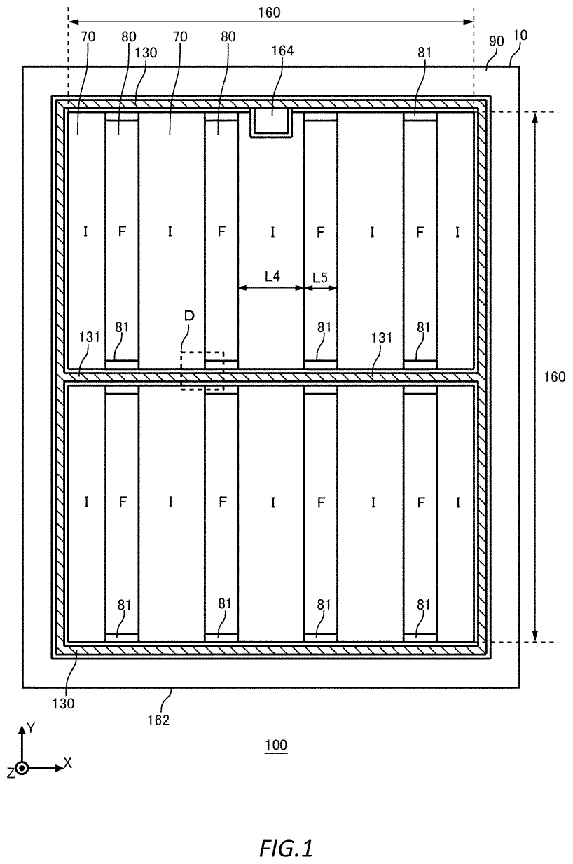

FIG. 1 illustrates a top view showing one example of the semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched by the active portion 160 in the top view may also be included in the active portion 160.

The active portion 160 is provided with a transistor portion 70 including a transistor element such as an insulated gate bipolar transistor (IGBT), and a diode portion 80 including a diode element such as a freewheeling diode (FWD). In the example of FIG. 1, the transistor portion 70 and the diode portion 80 are alternately arranged along a predetermined first direction (the X axis direction in this example) on the upper surface of the semiconductor substrate 10. The semiconductor device 100 of this example is a reverse-conducting IGBT (RC-IGBT). A boundary region is arranged between the transistor portion 70 and the diode portion 80 in the X axis direction, but is omitted in FIG. 1.

In FIG. 1, a region where each of the transistor portions 70 is arranged is indicated by a symbol “I”, and a region where each of the diode portions 80 is arranged is indicated by a symbol “F”. Each of the transistor portions 70 and the diode portions 80 may have a longitudinal length in the Y axis direction. In other words, the length of each of the transistor portions 70 in the Y axis direction is larger than the width in the X axis direction. Similarly, the length of each of the diode portions 80 in the Y axis direction is larger than the width in the X axis direction. The longitudinal direction of the transistor portion 70 and the diode portion 80 may be the same as the longitudinal direction of each trench portion described below. The longitudinal direction of the transistor portion 70 and the diode portion 80 may be the same as the longitudinal direction of the mesa portion described below.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type of may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is the P type region having a higher concentration than the base region described below, and is formed to a position deeper than the base region from the upper surface of the semiconductor substrate 10. A region enclosed by the well region in the top view may be the active portion 160.

The outer circumferential gate runner 130 is connected to the gate pad 164. The outer circumferential gate runner 130 is arranged above the semiconductor substrate 10. The outer circumferential gate runner 130 may be a wiring formed of a semiconductor such as polysilicon doped with an impurity or a metal wiring including aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity or a metal wiring including aluminum or the like.

The active-side gate runner 131 may be connected to the outer circumferential gate runner 130. The active-side gate runner 131 of this example is provided extending in the X axis direction so as to cross the active portion 160 from one side of the outer circumferential gate runner 130 to the other side of the outer circumferential gate runner 130 substantially at the center of the Y axis direction, the outer circumferential gate runner 130 sandwiching the active portion 160. When the active portion 160 is divided by the active-side gate runner 131, the transistor portion 70 and the diode portion 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

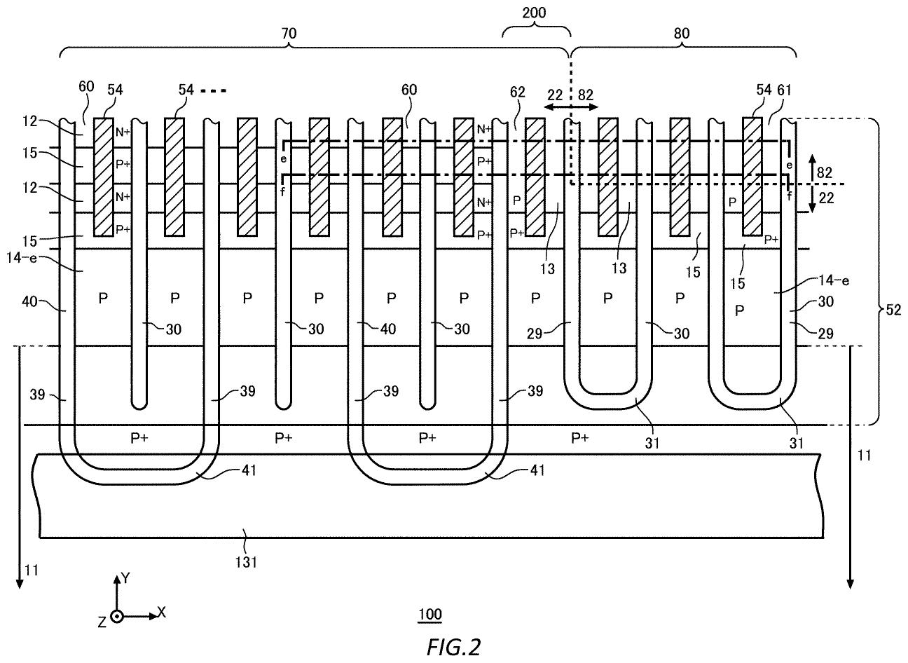

FIG. 2 illustrates an enlarged view of a region A in FIG. 1. The region D is a region including the transistor portion 70, the diode portion 80, and the active-side gate runner 131. Although omitted in FIG. 1, the transistor portion 70 may have a boundary region 200 adjacent to the diode portion 80 in the X axis direction. The transistor portion 70 may not have the boundary region 200. The semiconductor device 100 of this example includes a gate trench portion 40, a dummy trench portion 30, a well region 11, an emitter region 12, an anode region 13, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 is an example of an upper electrode. The emitter electrode 52 and the active-side gate runner 131 are provided separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the anode region 13, the base region 14, and the contact region 15. The emitter electrode 52 is in contact with the emitter region 12, the anode region 13, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and the gate conductive portion, and may be controlled to have a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The base region 14 of this example is a P type, and the well region 11 is a P+ type.

Each of the transistor portion 70, the diode portion 80, and the boundary region 200 includes a plurality of trench portions arranged in the X axis direction. In the transistor portion 70 of this example, one or more gate trench portions 40 and one or more dummy trench portions 30 are alternately provided along the X axis direction. In the diode portion 80 of this example, the plurality of dummy trench portions 30 is provided along the X axis direction. In the diode portion 80 of this example, the gate trench portion 40 is not provided. In the boundary region 200 of this example, the plurality of trench portions is provided along the first direction. The boundary region 200 may have at least one gate trench portion 40. The boundary region 200 may have at least one dummy trench portion 30. In the boundary region 200 of this example, at least one gate trench portion 40 and at least one dummy trench portion 30 are provided. However, the emitter region 12 is not formed in contact with the gate trench portion 40, and a channel is not formed and a current does not flow. In this example, the anode region 13 is exposed. In another example, the gate trench portion 40 may not be provided in the boundary region 200, and a plurality of dummy trench portions 30 may be provided.

The gate trench portion 40 of this example may have two linear portions 39 extending along the Y axis direction perpendicular to the X axis direction (portions of a trench that are linear along the Y axis direction), and the edge portion 41 connecting the two linear portions 39.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided or a plurality of dummy trench portions 30 may be provided. The dummy trench portion 30 may have a linear shape extending in the Y axis direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the X axis direction. The mesa portion refers to a region sandwiched between two of the plurality of trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the Y axis direction along the trench, on the upper surface of the semiconductor substrate 10. In the present specification, the Y axis direction may be referred to as the longitudinal direction of the mesa portion. In this example, the transistor portion 70 is provided with a mesa portion 60, the diode portion 80 is provided with a mesa portion 61, and the boundary region 200 is provided with a mesa portion 62. As merely referred to as the mesa portion in the specification, it indicates each of the mesa portion 60, the mesa portion 61, and the mesa portion 62.

The mesa portion 60 of the transistor portion 70 is provided with the base region 14. A region, which is arranged closest to the active-side gate runner 131, of the base region 14 exposed on the upper surface of the semiconductor substrate 10 in the mesa portion 60 is defined as a base region 14-e. While FIG. 2 shows the base region 14-e arranged at one end portion of each mesa portion 60 in the Y axis direction, the base region 14-e is also arranged at the other end portion of each mesa portion 60.

In the mesa portion 60 of the transistor portion 70, the emitter region 12 of a first conductivity type may be provided in a region sandwiched between the base regions 14-e in the top view. The mesa portion 60 may be provided with the contact region 15 of a second conductivity type. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of this example has the emitter region 12 and the contact region 15 exposed on the upper surface of the semiconductor substrate 10. The emitter region 12 is provided in contact with the gate trench portion 40.

Each of the contact region 15 and the emitter region 12 in the mesa portion 60 is provided from one trench portion to the other trench portion in the X axis direction. As an example, the contact regions 15 and the emitter regions 12 of the mesa portion 60 are alternately arranged along the Y axis direction of the trench portion.

In another example, the contact region 15 and the emitter region 12 of the mesa portion 60 may be provided in a stripe shape along the Y axis direction of the trench portion. For example, the emitter region 12 is provided in a region in contact with the trench portion, and the contact region 15 is provided in a region sandwiched between the emitter regions 12.

In the mesa portion 61 of the diode portion 80 of this example, the anode region 13 of the second conductivity type is provided in a region sandwiched between the base regions 14-e in the top view. The anode region 13 may be arranged instead of the base region 14-e. The mesa portion 61 may be provided with the contact region 15 of the second conductivity type. The anode region 13 may have the same doping concentration as that of the base region 14 and may have a lower doping concentration than that of the base region 14.

The mesa portion 61 of this example has the anode region 13 and the contact region 15 exposed on the upper surface of the semiconductor substrate 10. The contact region 15 may be provided in contact with the base region 14-e. The anode region 13 may be provided in a region sandwiched between the contact regions 15 in the Y axis direction. Each of the contact region 15 and the anode region 13 in the mesa portion 61 is provided from one trench portion to the other trench portion in the X axis direction.

The mesa portion 62 of the boundary region 200 in this example may have the same structure as that of the mesa portion 61 on the upper surface of the semiconductor substrate 10. For example, the mesa portion 62 may have the anode region 13 and the contact region 15 exposed on the upper surface of the semiconductor substrate 10. In another example, the mesa portion 62 may have the base region 14 instead of the anode region 13 of the mesa portion 61. In addition, the mesa portion 62 may have a structure in which the emitter region 12 is replaced with the anode region 13 in the structure of the mesa portion 60 on the upper surface of the semiconductor substrate 10. That is, the anode region 13 and the contact region 15 may be alternately arranged on the upper surface of the mesa portion 62 in the Y axis direction.

The contact hole 54 is provided above each mesa portion. The contact hole 54 is arranged in the region sandwiched between the base regions 14-e. The contact hole 54 of this example is provided above respective regions of the anode region 13, the contact region 15, and the emitter region 12. The contact hole 54 is not provided in regions corresponding to the base region 14-e and the well region 11. The contact hole 54 may be arranged at the center of the mesa portion 60 in the X axis direction.

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged separately from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54. A boundary position in the X axis direction between the cathode region 82 and the collector region 22 is a boundary position in the X axis direction between the diode portion 80 and the transistor portion 70. When the transistor portion 70 has the boundary region 200, the boundary position in the X axis direction between the cathode region 82 and the collector region 22 is a boundary position in the X axis direction between the diode portion 80 and the boundary region 200.

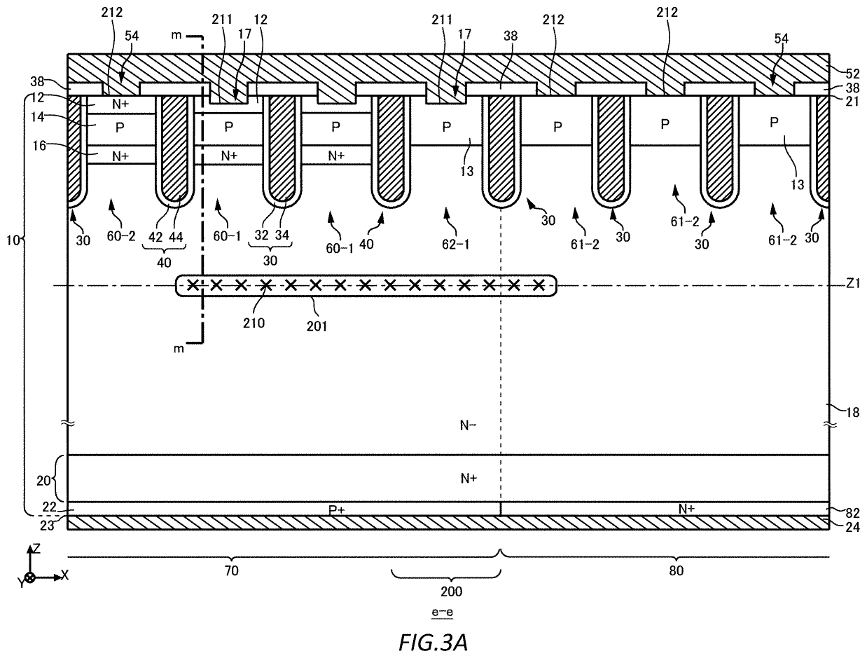

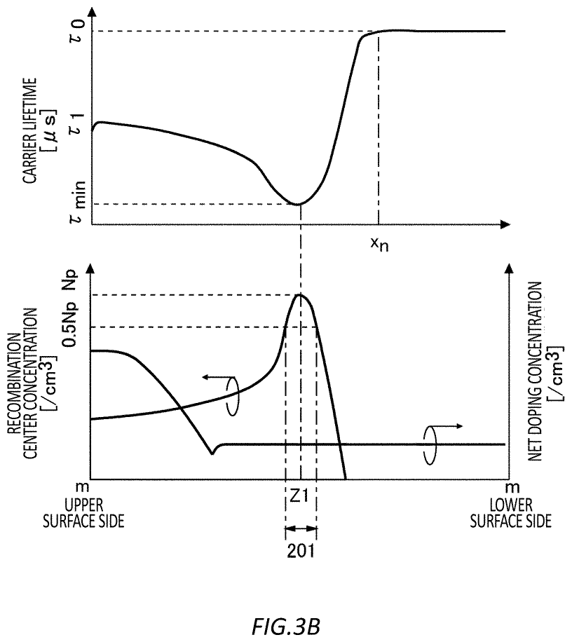

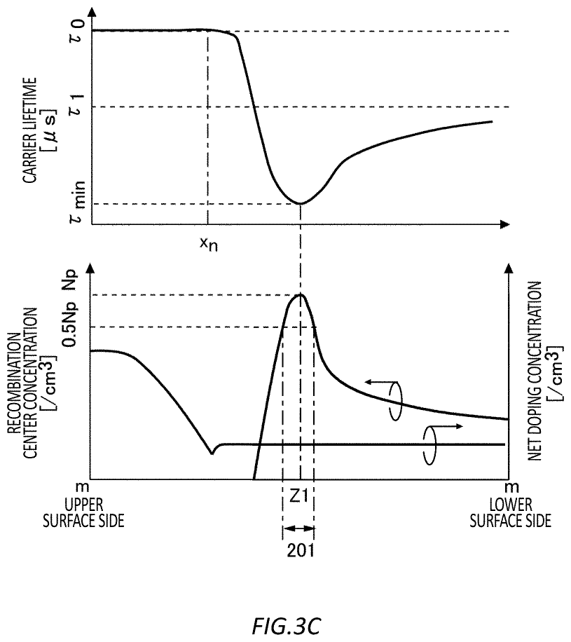

FIG. 3A illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface 21 of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the Z axis direction) is referred to as a depth direction.

The semiconductor substrate 10 includes an N type or N− type drift region 18. The drift region 18 is provided in each of the transistor portion 70, the diode portion 80, and the boundary region 200.

In the mesa portion 60 of the transistor portion 70, an N+ type of emitter region 12 and a P type of base region 14 are provided in order from an upper surface 21 side of the semiconductor substrate 10. The drift region 18 is provided below the base region 14. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the anode region 13 of the P type in contact with the upper surface 21 of the semiconductor substrate 10. The doping concentration of the anode region 13 may be the same as or different from the doping concentration of the base region 14. The drift region 18 is provided below the anode region 13. In at least a part of the mesa portion 62, the accumulation region 16 may be provided below the anode region 13. In at least a part of the mesa portion 61, the accumulation region 16 may be provided below the anode region 13. The mesa portion 62 of the boundary region 200 of this example has a similar structure to that of the mesa portion 61 on the upper surface 21 side of the semiconductor substrate 10.

In each of the transistor portion 70, the diode portion 80, and the boundary region 200, a buffer region 20 of the N+ type may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region of the P+ type 22 and the cathode region of the N+ type 82.

In the transistor portion 70, the collector region of the P+ type 22 is provided below the buffer region 20. When the boundary region 200 is provided in the transistor portion 70, the boundary region 200 is also provided with the collector region 22. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the above described example.

A boundary position in the X axis direction between the cathode region 82 and the collector region 22 is set as a boundary position in the X axis direction between the diode portion 80 and the transistor portion 70 (or the boundary region 200). In addition, the gate trench portion 40, which is arranged closest to the diode portion 80 in the X axis direction, among the gate trench portions 40 in contact with the emitter regions 12 is defined as a boundary trench portion. The boundary trench portion is set as a boundary position in the X axis direction between the boundary region 200 in the transistor portion 70 and a region other than the boundary region 200. The central position of the boundary trench portion in the X axis direction may be to be a boundary position in the X axis direction between the boundary region 200 and a region other than the boundary region 200. Among two trench portions in contact with the emitter region 12 arranged closest to the diode portion 80 in the X axis direction, the trench portion on the diode portion 80 side may be the dummy trench portion 30. The dummy trench portion 30 in this case may be a boundary trench portion in the X axis direction between the transistor portion 70 and the boundary region 200. For example, in the boundary region 200, the structure of the mesa portion 61 arranged on the upper surface 21 side of the semiconductor substrate 10 is the same as that of the diode portion 80, and the structure on the lower surface 23 side (in this example, the collector region 22 and the buffer region 20) is the same as that of the transistor portion 70.

The length of the transistor portion 70 in the X axis direction shown in FIG. 1 is defined as a fourth length L4. The fourth length L4 may be a length from one boundary position of the transistor portion 70 in the X axis direction to the other boundary position of the transistor portion 70 in the X axis direction. For example, the boundary position of the transistor portion 70 is a boundary position between the cathode region 82 and the collector region 22. The length of the diode portion 80 shown in FIG. 1 is defined as a fifth length L5. The fifth length L5 may be a length from one boundary position of the diode portion 80 in the X axis direction to the other boundary position of the diode portion 80 in the X axis direction. For example, the boundary position of the diode portion 80 is the boundary position between the cathode region 82 and the collector region 22.

The boundary region 200 may be provided with the emitter region 12. However, in this case, the gate trench portion 40 is not provided in the boundary region 200. In addition, the trench portion at the boundary position between the transistor portion 70 and the boundary region 200 may be the dummy trench portion 30. The gate trench portion 40 may be provided in the boundary region 200. However, in this case, the emitter region 12 is not provided in the boundary region 200. That is, in the boundary region 200, a transistor operation in which the emitter region 12 and the drift region 18 conduct with each other does not occur. The boundary region 200 is a buffer structure for arranging different structures of the transistor portion 70 and the diode portion 80 in parallel. Therefore, the width of the boundary region 200 in the X axis direction may be short. For example, the boundary region 200 may be provided with one or several mesa portions. The boundary region of 200 may not be provided. On the other hand, the width of the boundary region 200 in the X axis direction can be made longer by providing a plurality of mesa portions, adjusting the width of the mesa portion, or the like. The influence of the transistor portion 70 on the characteristics of the diode portion 80, for example, the influence of the operation of the gate trench portion 40 or the discharge or implantation of holes of the contact region 15 on a forward voltage or reverse recovery characteristics, or the like can be suppressed by providing the boundary region 200 having a long width.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided to pass through the base region 14 or the anode region 13 from the upper surface 21 of the semiconductor substrate 10 and reach below the base region 14. In a region where at least any one of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and the dummy trench portion 30. The diode portion 80 and the boundary region 200 of this example are provided with the dummy trench portion 30, and are not provided with the gate trench portion 40. However, at the boundary between the boundary region 200 and a region of the transistor portion 70 other than the boundary region 200, the gate trench portion 40 may be arranged, and in that case, the emitter region 12 is not formed in contact with the gate trench portion 40 in the boundary region 200. In another example, the dummy trench portion 30 may be arranged.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward.

The semiconductor device 100 of this example includes a first lifetime adjustment region 201 including lattice defects 210 which adjust the lifetime of carriers. The first lifetime adjustment region 201 of this example is a region in which the lifetime of charge carriers is locally small. The charge carriers are electrons or holes. The charge carriers may be referred to simply as carriers.

By implanting charged particles such as helium ions into the semiconductor substrate 10, the lattice defects 210 such as vacancies are formed in the vicinity of the implantation position. The lattice defects 210 generate a recombination center. The lattice defects 210 may be mainly composed of vacancies such as monatomic vacancies (V) and diatomic vacancies or divacancies (VV), may be dislocations, may be interstitial atoms, or may be transition metals or the like. For example, atoms adjacent to the vacancies have dangling bonds. In a broad sense, the lattice defects 210 may also include donors and acceptors, but in the present specification, the lattice defects 210 mainly composed of vacancies may be referred to as vacancy-type lattice defects, vacancy-type defects, or simply lattice defects. In the present specification, the lattice defects 210 may be simply referred to as a recombination center or a lifetime killer as a recombination center contributing to the carrier recombination. The lifetime killer may be formed by implanting helium ions into the semiconductor substrate 10. In this case, a helium chemical concentration may be used as the density of the lattice defects 210. Note that since the lifetime killer formed by implanting helium ions may be terminated by hydrogen existing in the buffer region 20, the depth position of the density peak of the lifetime killer may not be identical to the depth position of the helium chemical concentration peak. In addition, when hydrogen ions are implanted into the semiconductor substrate 10, the lifetime killer may be formed in the passed-through region of hydrogen ions on the implantation surface side from a projected range.

In FIG. 3A, the lattice defects 210 at the implantation position of charged particles are schematically indicated by x marks. In a region where many lattice defects 210 remain, carriers are captured by the lattice defects 210, so that the lifetime of the carriers is shortened. By adjusting the lifetime of the carrier, it is possible to adjust characteristics such as a reverse recovery time and a reverse recovery loss of a region operating as a diode in the vicinity of the first lifetime adjustment region 201. The position at which the carrier lifetime indicates the minimum value in the depth direction of the semiconductor substrate 10 may be set to a first depth Z1 at which the first lifetime adjustment region 201 is provided.

The first lifetime adjustment region 201 is arranged at the first depth Z1 on the upper surface 21 side of the semiconductor substrate 10. The upper surface 21 side is a region from a central position of the semiconductor substrate 10 in the depth direction to the upper surface 21 of the semiconductor substrate 10. The first lifetime adjustment region 201 of this example is arranged below the lower end of the trench portion.

The density of the lattice defects 210 in the first lifetime adjustment region 201 is a first defect density. The defect density corresponds to the number of lattice defects per unit volume. As described above, the chemical concentration (atoms/cm³) of impurities such as helium may be used as a value indicating the defect density. In another example, the reciprocal of the lifetime of minority carriers may be used as the value indicating the defect density. The maximum value of the density of the lattice defects 210 in the depth direction may be treated as the defect density in the first lifetime adjustment region 201. The position at which the defect density in the depth direction indicates the maximum value may be the first depth Z1 at which the first lifetime adjustment region 201 is provided.

The first lifetime adjustment region 201 is provided in a predetermined range in the top view. The first lifetime adjustment region 201 has the first defect density at each position in the top view. However, the defect density at each position of the first lifetime adjustment region 201 in the top view may have a predetermined error from each other. The error is, for example, within ±20%. For example, a region exhibiting a defect density of 60% or more with respect to the maximum value of the defect density in the first lifetime adjustment region 201 may be set as the first lifetime adjustment region 201, a region exhibiting a defect density of 80% or more may be set as the first lifetime adjustment region 201, or a region exhibiting a defect density of 90% or more may be set as the first lifetime adjustment region 201.

The first lifetime adjustment region 201 includes a region provided in at least one of the transistor portion 70 or the diode portion 80. In the example of FIG. 3A, the first lifetime adjustment region 201 includes a region provided in the transistor portion 70 and a region provided in the diode portion 80. In this example, the first lifetime adjustment region 201 is provided in a portion in contact with the boundary region 200 in the diode portion 80. In addition, the first lifetime adjustment region 201 is provided in the boundary region 200 and a portion in contact with the boundary region 200 in the transistor portion 70.

A plurality of mesa portions includes one or more first mesa portions and one or more second mesa portions. The first mesa portion is a mesa portion provided with the first lifetime adjustment region 201 therebelow and being in contact with the emitter electrode 52. In the first mesa portion, a portion in contact with the emitter electrode 52 is defined as a first contact portion 211. The second mesa portion is a mesa portion not provided with the first lifetime adjustment region 201 therebelow, or provided with a region having a lower density of the lattice defects 210 than that of the first lifetime adjustment region 201 and being in contact with the emitter electrode 52. In the second mesa portion, the portion in contact with the emitter electrode 52 is defined as a second contact portion 212. The mesa portion having a region not overlapping the first lifetime adjustment region 201 in the top view may be defined as the second mesa portion. In the example of FIG. 3A, the mesa portion 61 in contact with the boundary region 200 in the diode portion 80 partially overlaps the first lifetime adjustment region 201. The mesa portion 61 is defined as the second mesa portion. In another example, the mesa portion having a region overlapping the first lifetime adjustment region 201 in the top view may be defined as the first mesa portion.

In the example of FIG. 3A, a mesa portion 60-1 and a mesa portion 62-1 are the first mesa portions. In addition, a mesa portion 60-2 and a mesa portion 61-2 in FIG. 3A are the second mesa portions.

A first depth position of the first contact portion 211 of at least one first mesa portion (in this example, the mesa portions 60-1 or 62-1) is different from a second depth position of the second contact portion 212 of at least one second mesa portion (in this example, the mesa portions 60-2 or 61-2). The first depth position and the second depth position are positions in the Z axis direction with respect to the upper surface 21 of the semiconductor substrate 10. In the present specification, inside the semiconductor substrate 10, a position close to the upper surface 21 of the semiconductor substrate 10 may be referred to as “shallow”, and a position away from the upper surface 21 may be referred to as “deep”.

Configuring the first contact portion 211 of at least one first mesa portion and the second contact portion 212 of at least one second mesa portion to have mutually different depth positions allows the characteristics of the semiconductor device 100 to be easily adjusted. The first contact portions 211 of the plurality of first mesa portions may be provided at the first depth position. That is, the first contact portions 211 of the plurality of first mesa portions may be provided at a depth position different from the depth position of the second contact portion 212 of the second mesa portion. The first contact portions 211 of all the first mesa portions may be provided at the first depth position. That is, the first contact portions 211 of all the first mesa portions may be provided at a depth position different from the depth position of the second contact portion 212 of the second mesa portion.

One of the first depth position and the second depth position may be the same depth position as the upper surface 21 of the semiconductor substrate 10. Another of the first depth position and the second depth position may be a position deeper than the upper surface 21 of the semiconductor substrate 10. For example, by providing the trench contact portion 17 on the upper surface of the mesa portion, the contact portion where the mesa portion and the emitter electrode 52 are in contact with each other can be provided at a deeper position. When the upper surface of the mesa portion is not flat as in the example in which the trench contact portion 17 is provided, the contact portion of the mesa portion is a portion provided at the deepest position in the portion where the mesa portion and the emitter electrode 52 are in contact with each other. For example, when the trench contact portion 17 is provided in the mesa portion, the contact portion of the mesa portion is the bottom surface of the trench contact portion 17.

In the example of FIG. 3A, the first depth position is provided at a position deeper than the second depth position with respect to the upper surface 21 of the semiconductor substrate 10. At least one first contact portion 211 includes the trench contact portion 17 in which the emitter electrode 52 is provided inside the semiconductor substrate 10. The trench contact portion 17 may be formed by filling a metal material in a trench formed by etching the upper surface of the mesa portion. The first depth position in this example is the depth position of the bottom surface of the trench contact portion 17 provided in the first contact portion 211. The trench contact portion 17 may be arranged below the contact hole 54. The trench contact portion 17 may have the same length as the contact hole 54 in the Y axis direction.

The second depth position in this example is the depth position of the second contact portion 212 provided on the upper surface 21 of the semiconductor substrate 10. The lower end of the second contact portion 212 of this example is arranged on the upper surface 21 of the semiconductor substrate 10. The second contact portion 212 may be a part of the upper surface 21 of the semiconductor substrate 10. In the example of FIG. 3A, the first contact portions 211 of all the first mesa portions are provided with the trench contact portions 17, and the second contact portions 212 of all the second mesa portions are arranged on the upper surface 21. In another example, similarly, the first contact portions 211 of all the first mesa portions may be provided with the trench contact portions 17, and the second contact portions 212 of all the second mesa portions may be arranged on the upper surface 21.

The transistor portion 70 may have at least one first mesa portion. In the first mesa portion arranged closest to the diode portion 80 among the first mesa portions of the transistor portion 70, the first contact portion 211 may be provided at the first depth position. The first mesa portion arranged closest to the diode portion 80 may be provided with the trench contact portion 17. All the first mesa portions (mesa portions 60-1) arranged in the transistor portion 70 may be provided with the trench contact portions 17.

In the example of FIG. 3A, the mesa portion 62-1 of the boundary region 200 is the first mesa portion. In another example, the mesa portion 62 of the boundary region 200 may be the second mesa portion. That is, the first lifetime adjustment region 201 may not be provided in the boundary region 200. In this case, the trench contact portion 17 may not be provided in the mesa portion 62 of the boundary region 200.

In the example of FIG. 3A, in the mesa portion 60 of the transistor portion 70, the mesa portion 60-2 away from the boundary region 200 is the second mesa portion. The transistor portion 70 may be provided with one or more first mesa portions. In the example of FIG. 3A, one mesa portion 60 included in the boundary region 200 of the transistor portion 70 and two mesa portions 60 provided closest to the boundary region 200 are the first mesa portions. The plurality of first mesa portions may be provided with the trench contact portions 17.

In the example of FIG. 3A, the first lifetime adjustment region 201 is provided in a part of the diode portion 80. In another example, the first lifetime adjustment region 201 may be provided over the entire diode portion 80 in the X axis direction. That is, all the mesa portions of the diode portion 80 may be the first mesa portion. The trench contact portion 17 may or may not be provided in the first mesa portion arranged in the diode portion 80.

In each example described in the present specification, among one or more mesa portions provided in the transistor portion 70 and the diode portion 80, all mesa portions in which the contact portion in contact with the emitter electrode 52 is provided at the first depth position may be the first mesa portions. That is, all the mesa portions in which the contact portion is provided at the first depth position may be provided with the first lifetime adjustment regions 201.

FIG. 3B shows the concentration distribution, the net doping concentration distribution, and the carrier lifetime distribution of the recombination center in the Z axis direction in the first lifetime adjustment region 201 along the cross section m-m of FIG. 3A. The first lifetime adjustment region 201 of this example is formed by radiating helium ions from the upper surface 21 side of the semiconductor substrate 10.

The concentration of the lifetime killer (recombination center) in the first lifetime adjustment region 201 becomes a peak concentration Np at the first depth Z1. The depth position is arranged in the drift region 18 nearer to the upper surface 21 side than the center of the semiconductor substrate 10 in the depth direction. A region having a lifetime killer with a higher concentration than the half value 0.5 Np of the peak concentration Np may be set as the first lifetime adjustment region 201.

When helium ions or the like are radiated from the upper surface 21 side, the tail of the distribution of the lifetime killer having a concentration lower than the peak concentration Np is drawn from the peak position Z1 to the upper surface 21 of the semiconductor substrate 10 such that the concentration gradually decreases. On the other hand, the concentration of the lifetime killer on the lower surface 23 side of the semiconductor substrate 10 with respect to the peak position Z1 decreases more steeply than the concentration of the lifetime killer on the upper surface 21 side of the semiconductor substrate 10 with respect to the peak position Z1. The concentration distribution in the first lifetime adjustment region 201 may not reach the lower surface 23.

As long as the distribution has a tail drawn continuously from the upper surface 21 to the position of the peak concentration Np, the depth position Z1 of the peak concentration Np may be on the lower surface 23 side with respect to the intermediate position of the semiconductor substrate 10 in the depth direction.

The concentration of the recombination center shown in FIG. 3B may be a helium concentration as described above, or may be the density of crystal defects formed by helium radiation. The crystal defects may be dangling bonds, which are formed by vacancies and the like, such as interstitial helium, vacancies, and double vacancies. Due to these crystal defects, the recombination center of the carriers is formed. The recombination of the carriers is facilitated through an energy level (trap level) of the formed energy recombination center. A recombination center concentration corresponds to a trap level density.

The carrier lifetime distribution shown in FIG. 3B has a minimum value τₘᵢₙ at a position substantially corresponding to the peak position Z1 of the recombination center concentration. In the base region 14 near the upper surface 21, the carrier lifetime distribution may have a value τ₁ larger than τₘᵢₙ. In a region where the lifetime killer is not introduced, the carrier lifetime distribution may be distributed with a substantially uniform value (denoted by τ₀). In this example, the carrier lifetime is τ₀ in the region on the lower surface 23 side with respect to a depth position xₙ. The depth position xₙ in this example is a position in the drift region 18 deeper than the depth position Z1. The value τ₀ is larger than the value τ₁. In the top view, the value of the carrier lifetime at the depth position Z1 may be τ₀ in a region other than the first lifetime adjustment region 201, that is, another region in which the lifetime killer is not introduced.

FIG. 3C shows another example of the concentration distribution, the net doping concentration distribution, and the carrier lifetime distribution of the recombination center in the Z axis direction in the first lifetime adjustment region 201 along the cross section m-m of FIG. 3A. The example of FIG. 3C is different from the example of FIG. 3B in that the first lifetime adjustment region 201 is formed by radiating a lifetime killer such as helium ions from the lower surface 23 side of the semiconductor substrate 10.

When helium ions or the like are radiated from the lower surface 23 side, the tail of the distribution of the lifetime killer having a concentration lower than the peak concentration Np is drawn from the peak position Z1 toward the lower surface 23 of the semiconductor substrate 10 such that the concentration gradually decreases. On the other hand, the concentration of the lifetime killer on the upper surface 21 side of the semiconductor substrate 10 with respect to the peak position Z1 decreases more steeply than the concentration of the lifetime killer on the lower surface 23 side of the semiconductor substrate 10 with respect to the peak position Z1. The concentration distribution in the first lifetime adjustment region 201 may not reach the upper surface 21.

The carrier lifetime distribution shown in FIG. 3C has a minimum value τₘᵢₙ at a depth position substantially corresponding to the peak position Z1 of the recombination center concentration. Between the depth position Z1 and the lower surface 23, the carrier lifetime distribution may have the value τ₁ larger than τₘᵢₙ.

In the region where the lifetime killer is not introduced, the carrier lifetime distribution may be distributed with the substantially uniform value τ₀. In this example, the carrier lifetime is to in the region on the upper surface 21 side with respect to the depth position xₙ. The depth position xₙ in this example is a position on the upper surface 21 side with respect to the depth position Z1. The value τ₀ is larger than the value τ₁. However, in a region where the concentration of the dopant is higher than that in the drift region 18, the value of the carrier lifetime may be lower than to. In the top view, the value of the carrier lifetime at the depth position Z1 may be to in a region other than the first lifetime adjustment region 201, that is, another region in which the lifetime killer is not introduced.

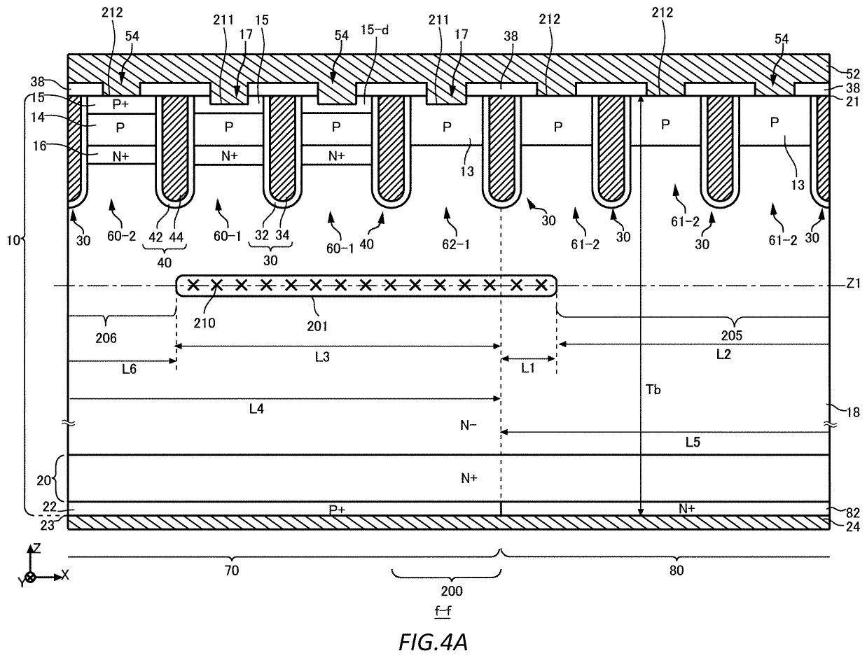

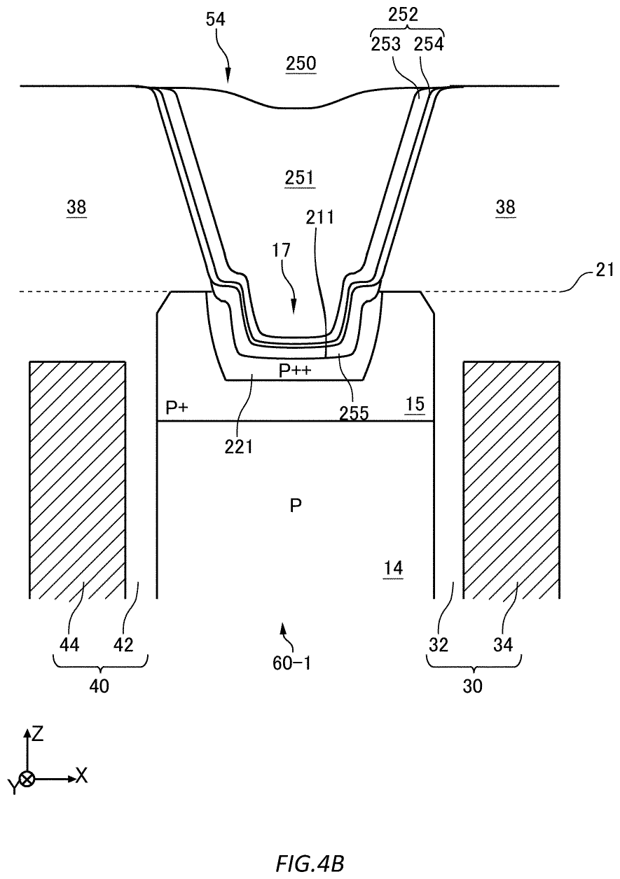

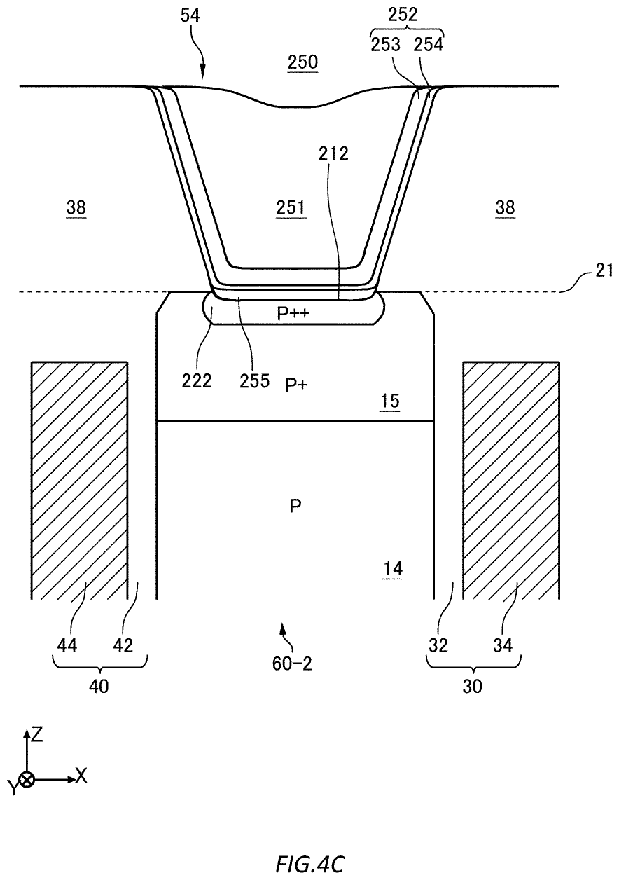

FIG. 4A illustrates a view showing an example of a cross section f-f in FIG. 2. The cross section f-f is an XZ plane passing through the contact region 15 of the transistor portion 70 and the cathode region 82. The structure of the semiconductor device 100 in the cross section f-f of FIG. 4A is different from the structure of the cross section e-e in that the contact region 15 is provided instead of the emitter region 12 in the structure of the cross section e-e shown in FIG. 3A. Other structures are similar to those of the cross section e-e.

Also in the cross section f-f, the first lifetime adjustment region 201 is provided at the first depth Z1 on the upper surface 21 side of the semiconductor substrate 10. As shown in FIGS. 3A and 4A, the first lifetime adjustment region 201 includes a region, which is provided in the vicinity of the diode portion 80, of the transistor portion 70. More specifically, the first lifetime adjustment region 201 includes a region which is arranged below a contact region 15-d, which is closest to the diode portion 80 in the X axis direction, among the contact regions 15 of the transistor portion 70. The doping concentration of the contact region 15 may be 10 times or more, 50 times or more, or 100 times or more the doping concentration of the base region 14. The contact region 15-d may be the contact region 15, which is closest to the diode portion 80, among the contact regions 15 other than the contact region 15 in contact with the base region 14-e described in FIG. 2.

During a diode operation in which the transistor portion 70 is turned off and a main current flows through the diode portion 80, many holes are implanted into the drift region 18 from the contact region 15 which is the P+ type of a high concentration. The holes implanted from the contact region 15 arranged near the diode portion 80 may reach the drift region 18 of the diode portion 80. For this reason, the holes implanted from the contact region 15 influence characteristics such as a reverse recovery time and a reverse recovery loss of the diode portion 80. The influence of each contact region 15 on the characteristics of the diode portion 80 increases as the contact region 15 is closer to the diode portion 80.

In the semiconductor device 100 of this example, the first lifetime adjustment region 201 is provided below the contact region 15-d. With this configuration, the lifetime of the holes flowing from the contact region 15-d having a large influence on the diode portion 80 to the diode portion 80 can be adjusted, and the characteristics such as the reverse recovery time and the reverse recovery loss of the diode portion 80 can be adjusted efficiently. The first lifetime adjustment region 201 may be provided in a range wider than the width of the contact region 15-d in the X axis direction.

By providing the first lifetime adjustment region 201 in the diode portion 80, the lifetime of the holes implanted from the anode region 13 can be easily adjusted. On the other hand, when the first lifetime adjustment region 201 is provided, a leakage current flowing through the emitter electrode 52 increases.

In this example, the first lifetime adjustment region 201 is not provided in at least a partial region of the diode portion 80 in the X axis direction. With this configuration, since an area in which the first lifetime adjustment region 201 is provided can be reduced, the leakage current flowing through the emitter electrode 52 can be reduced.

A length in the X axis direction by which the first lifetime adjustment region 201 is provided in the diode portion 80 is defined as a first length L1. A length, in the X axis direction, of the region in the diode portion 80 where the first lifetime adjustment region 201 is not provided is defined as a second length L2.

The first length L1 may be 0. In other words, the first lifetime adjustment region 201 may not be provided in the diode portion 80. Alternatively, the first length L1 may be smaller than the second length L2. With this configuration, the leakage current flowing through the emitter electrode 52 can be reduced. The first length L1 may be 50% or less, 25% or less, 10% or less, or 5% or less of the second length L2.

The first length L1 may be 40% or less of the length (L1+L2) of the diode portion 80 in the X axis direction. The first length L1 may be 20% or less or 10% or less of the length (L1+L2) of the diode portion 80 in the X axis direction. When the first length L1 is 10% or less of the length (L1+L2) of the diode portion 80 in the X axis direction, the leakage current can be set to have the substantially same value as that when the first length L1 is 0% (that is, when the first length L1 is 0).

In the diode portion 80 of this example, the contact region 15 is not provided at least in a range overlapping the cathode region 82. For this reason, even if the first lifetime adjustment region 201 in the diode portion 80 is reduced or eliminated, the reverse recovery time, the reverse recovery loss, and the like of the diode portion 80 do not become so large. In addition, the doping concentration of the anode region 13 may be smaller than the doping concentration of the base region 14. With this configuration, the amount of holes implanted from the anode region 13 can be reduced, and characteristics such as the reverse recovery time and the reverse recovery loss of the diode portion 80 can be adjusted. The doping concentration of the anode region 13 may be 50% or less, 25% or less, or 10% or less of the doping concentration of the base region 14. The doping concentration of the anode region 13 may be 1% or more of the doping concentration of the base region 14. The doping concentration of the anode region 13 may be 2 times or more, 5 times or more, or 10 times or more the doping concentration of the drift region 18.

As described above, the first lifetime adjustment region 201 includes a region which is arranged below the contact region 15-d, which is closest to the diode portion 80 in the X axis direction, among the contact regions 15 of the transistor portion 70. The first lifetime adjustment region 201 provided in the transistor portion 70 may include a region below the mesa portion 62 of the boundary region 200. For example, when the contact region 15-d is provided in the mesa portion 62, the first lifetime adjustment region 201 is provided below the mesa portion 62. The collector region 22 may be arranged on the lower surface of the mesa portion 62, and the contact region 15-d may not be provided on the upper surface. With this configuration, the influence of the holes implanted from the mesa portion 62 on the diode portion 80 can be reduced. The emitter region 12 may not be provided on the upper surface of the mesa portion 62. When the first lifetime adjustment region 201 is provided below the mesa portion 62 of the boundary region 200, the first lifetime adjustment region 201 may extend or may not extend to the diode portion 80.

When the contact region 15-d is not arranged in the mesa portion 62, the first lifetime adjustment region 201 may or may not be provided below the mesa portion 62. When the first lifetime adjustment region 201 is not provided below the mesa portion 62, the diode portion 80 may not be provided with the first lifetime adjustment region 201. When the first lifetime adjustment region 201 is provided below the mesa portion 62, the first lifetime adjustment region 201 below the mesa portion 62 may extend or may not extend to the diode portion 80.

A length, in the X axis direction, of the first lifetime adjustment region 201 provided in the transistor portion 70 is defined as a third length L3. The first length L1 may be smaller than the third length L3. The first length L1 may be 50% or less, 25% or less, 10% or less, or 5% or less of the third length L3. A length, in the X axis direction, of the region in the transistor portion 70 where the first lifetime adjustment region 201 is not provided is defined as a sixth length L6. The sixth length L6 may be longer than the third length L3, and may be longer than the total value of the third lengths L3. The total value of the third lengths L3 is the total value of the third lengths L3 of one or more first lifetime adjustment regions 201 included in one transistor portion 70.

The third length L3 may be smaller than the length (fourth length L4) of the transistor portion 70 in the X axis direction. The third length L3 may be 2 times or less, 1 time or less, 0.8 times or less, 0.6 times or less, 0.4 times or less, or 0.2 times or less a thickness Tb of the semiconductor substrate in the depth direction. The third length L3 may be 0.01 times or more, 0.03 times or more, 0.05 times or more, or 0.1 times or more the thickness Tb. By ensuring the third length L3, it is possible to reduce the influence of the holes implanted from the contact region 15 of the transistor portion 70 on the diode portion 80.

The total value of the third lengths L3 in the transistor portion 70 may be smaller than the length (fourth length L4) of the transistor portion 70 in the X axis direction. The total value of the third lengths L3 may be a value obtained by adding the third length L3 at one end portion of the transistor portion 70 and the third length L3 at the other end portion of the same transistor portion 70. The total value of the third lengths L3 may be 50% or less, 30% or less, or 10% or less of the fourth length L4. The total value of the third lengths L3 is set to be shorter than the fourth length L4, so that it is possible to reduce the conduction loss (saturation voltage) of the transistor portion 70 and the leakage current. The total value of the third lengths L3 is set to 10% or less of the fourth length L4, so that the conduction loss (saturation voltage) or the leakage current can be made to be equal to that when the total value of the third lengths is 0.

The length, in the X axis direction, of the region in the transistor portion 70 where the first lifetime adjustment region 201 is not provided is defined as the sixth length L6. The sixth length L6 may be longer than the third length L3, and may be longer than the total value of the third lengths L3. This also makes it possible to reduce the conduction loss (saturation voltage) of the transistor portion 70 and the leakage current. The first length L1 of the diode portion 80 may be 25% or less, 10% or less, or 5% or less of the thickness Tb of the semiconductor substrate 10 in the depth direction.

In each aspect described in the present specification, the diode portion 80 may have, below at least two of a plurality of mesa portions 61 arranged adjacent to each other in the X axis direction, a region 205 where the first lifetime adjustment region 201 is not provided. The carrier lifetime or the defect density in the region 205 may be the same as the carrier lifetime or the defect density at the center of the drift region 18 in the depth direction. The region 205 may be provided continuously below three or more mesa portions 61 adjacent to each other in the X axis direction, or may be provided continuously below four or more mesa portions 61.

The number of the mesa portions 61 provided with the first lifetime adjustment regions 201 in the diode portion 80 may be 4 or less, or may be 2 or less. When a plurality of first lifetime adjustment regions 201 of the diode portion 80 are provided in the X axis direction, the number of the mesa portions 61 is the total number of the mesa portions 61 provided with the first lifetime adjustment regions 201.

In each aspect described in the present specification, the transistor portion 70 may have, below at least two mesa portions 60 arranged adjacent to each other in the X axis direction, a region 206 where the first lifetime adjustment region 201 is not provided. The carrier lifetime or the defect density in the region 206 may be the same as the carrier lifetime or the defect density at the center of the drift region 18 in the depth direction. The region 206 may be provided continuously below three or more mesa portions 60 adjacent to each other in the X axis direction, or may be provided continuously below four or more mesa portions 60.

FIG. 4B illustrates an enlarged view of a periphery of the trench contact portion 17 shown in FIG. 4A. The emitter electrode 52 of this example includes a barrier metal 252, a plug electrode 251, and an upper portion 250. The barrier metal 252 is provided above the upper surface 21 of the semiconductor substrate 10. The barrier metal 252 is provided at least on the bottom surface of the contact hole 54. When the trench contact portion 17 is arranged at the lower end of the contact hole 54, the barrier metal 252 is provided at least on the bottom surface of the trench contact portion 17. The barrier metal 252 may be provided at the lower end of each contact portion. The barrier metal 252 may be in contact with the semiconductor substrate 10. The barrier metal 252 may also be provided on the side surfaces of the contact hole 54 and the trench contact portion 17. The barrier metal 252 may or may not be provided on the upper surface of the interlayer dielectric film 38.

The barrier metal 252 may be formed of a material having a higher hydrogen occlusion property than the plug electrode 251 or the upper portion 250. With this configuration, entry of hydrogen into the semiconductor substrate 10 is suppressed. The barrier metal 252 of this example contains titanium as an example. The barrier metal 252 may include a titanium nitride layer. The barrier metal 252 may be a laminated film of a titanium layer and a titanium nitride layer.

The plug electrode 251 is provided above the barrier metal 252 and inside the contact hole 54 or the trench contact portion 17. The plug electrode 251 may be formed of a material different from the barrier metal 252. As an example, the plug electrode 251 contains tungsten or copper. The plug electrode 251 may be provided above the interlayer dielectric film 38. In addition, the plug electrode 251 may not be provided. An upper portion 250 is provided above the barrier metal 252 and the plug electrode 251. The upper portion 250 may be formed of a material different from the barrier metal 252 and the plug electrode 251. As an example, the upper portion 250 may contain aluminum or copper alone or as an alloy, or may be formed by being laminated with a layer of a different metal such as nickel above aluminum or the like.

The barrier metal 252 of this example has a first layer 253 and a second layer 254. As an example, the first layer 253 is a titanium nitride layer provided between the plug electrode 251 or the upper portion 250 and the second layer 254 or a silicide layer 255. The second layer 254 is a titanium layer or a titanium nitride layer provided between the first layer 253 and the semiconductor substrate 10 or the interlayer dielectric film 38.

The barrier metal 252 may be in contact with the semiconductor substrate 10. The barrier metal 252 may further has the silicide layer 255. The silicide layer 255 is formed at a position in contact with the semiconductor substrate 10. The silicide layer 255 is a layer in which a part of the second layer 254 is silicided. At a position where the barrier metal 252 is in contact with the semiconductor substrate 10, all of the second layer 254 may be changed to the silicide layer 255 and may not be present.

A first plug region 221 is provided below the trench contact portion 17. The first plug region 221 is a P++ type region provided in contact with the lower end of the first contact portion 211 and having a higher doping concentration than the contact region 15. By providing the first plug region 221, the contact resistance between the P type region and the barrier metal 252 can be reduced, implantation and extraction of holes can be improved, and the leakage current can be reduced. In FIG. 4B, the first plug region 221 is provided in the entire portion around the trench contact portion 17, but in another example, the first plug region 221 may be provided only in a part, and for example, the first plug region 221 may not be provided in a place positioned on the side surface of the trench contact portion 17.

FIG. 4C illustrates an enlarged view of a periphery of the second contact portion 212 shown in FIG. 4A. The second contact portion 212 of this example is arranged at a position shallower than the first contact portion 211.

The structure shown in FIG. 4C is different from the example of FIG. 4B in that the trench contact portion 17 is not provided. In addition, in the structure shown in FIG. 4C, a second plug region 222 is provided instead of the first plug region 221. The second plug region 222 is a P++ type region provided in contact with the lower end of the second contact portion 212 and having a higher doping concentration than the contact region 15. By providing the second plug region 222, the contact resistance between the P type region and the barrier metal 252 can be reduced, implantation and extraction of holes can be improved, and the leakage current can be reduced. In FIG. 4C, the second plug region 222 is provided in the entire portion of the second contact portion 212 along the X direction, but in another example, the second plug region 222 may be provided only in a part, and for example, the second plug region 222 may be provided only at a place positioned at the center of the contact hole 54 in the X direction. Other structures are similar to those in the example of FIG. 4B.

At least a part of the first plug region 221 may be provided to overlap the contact region 15 in the top view. That is, the first plug region 221 may be provided in any XZ cross section passing through the contact region 15. At least a part of the second plug region 222 may be provided to overlap the contact region 15 in the top view. The first plug region 221 and the second plug region 222 may be provided at the same position in the Y axis direction.

The first plug region 221 and the second plug region 222 may be provided in an XZ cross section passing through the center of the contact region 15 in the Y axis direction. A part of the first plug region 221 and a part of the second plug region 222 may overlap the emitter region 12 in the top view. The first plug region 221 and the second plug region 222 may be provided in an end region of the emitter region 12 in contact with the contact region 15. The first plug region 221 and the second plug region 222 may not be provided in any XZ cross section passing through the emitter region 12. For example, the first plug region 221 and the second plug region 222 are not provided in the XZ cross section passing through the center of the emitter region 12 in the Y axis direction. The entire first plug region 221 may be provided to overlap the contact region 15. The entire second plug region 222 may be provided to overlap the contact region 15. In this case, the first plug region 221 and the second plug region 222 do not overlap the emitter region 12 in the top view.

The mesa portion 60 provided with the trench contact portion 17 can reduce a high concentration portion of the contact region 15 and can reduce hole implantation. In addition, by providing each plug region, holes are easily extracted in each mesa portion. For this reason, it is possible to suppress reduction in withstand capability.

The first lifetime adjustment region 201 is formed by radiation of charged particles from the upper surface 21. On the other hand, by the radiation of charged particles, a level is formed in the gate dielectric film 42 of the first mesa portion (for example, the mesa portion 60-1) above the first lifetime adjustment region 201. With this configuration, a threshold voltage (on-voltage, off-voltage) in the first mesa portion may be lower than a threshold voltage in the second mesa portion (for example, the mesa portion 60-2). When the threshold voltage decreases, a turn-off timing is delayed, and thus the turn-off of the first mesa portion may become later than the turn-off of the second mesa portion, so that current concentrates on the first mesa portion, and the withstand capability decreases.

The first contact portion 211 of the first mesa portion is positioned to be deeper than the second contact portion 212 by the trench contact portion 17 or the like, so that holes can be easily extracted from the semiconductor substrate 10 to the emitter electrode 52 in the first mesa portion. For this reason, even when the current concentrates on the first mesa portion, it is possible to suppress reduction in withstand capability.

The first plug region 221 of this example is arranged near a region (that is, the surface layer of the base region 14 in contact with the gate trench portion 40) where a channel is formed in the base region 14. For this reason, the channel portion of the base region 14 is hardly inverted to the N type, and the threshold voltage increases. Therefore, by providing the first plug region 221, it is possible to offset the reduction in threshold voltage due to the formation of the first lifetime adjustment region 201. The second plug region 222 is provided at a shallower position compared with the first plug region 221. For this reason, the increase in threshold voltage due to the provision of the second plug region 222 is relatively small. The threshold voltage of the second mesa portion tends to be lower than the threshold voltage of the first mesa portion due to the influence of the plug region, but the threshold voltage of the first mesa portion decreases by forming the first lifetime adjustment region 201. For this reason, a difference in threshold voltage between the first mesa portion and the second mesa portion becomes small.

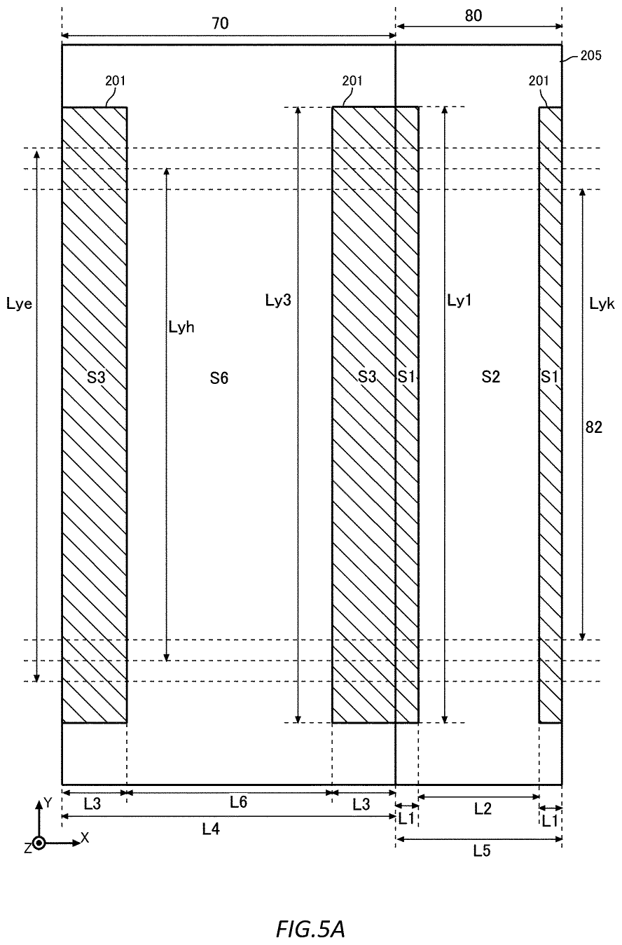

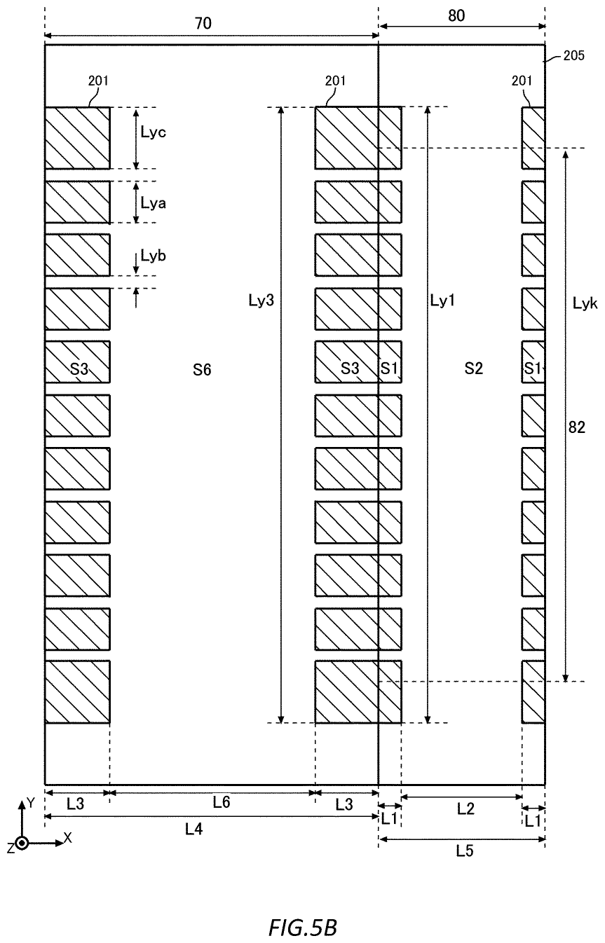

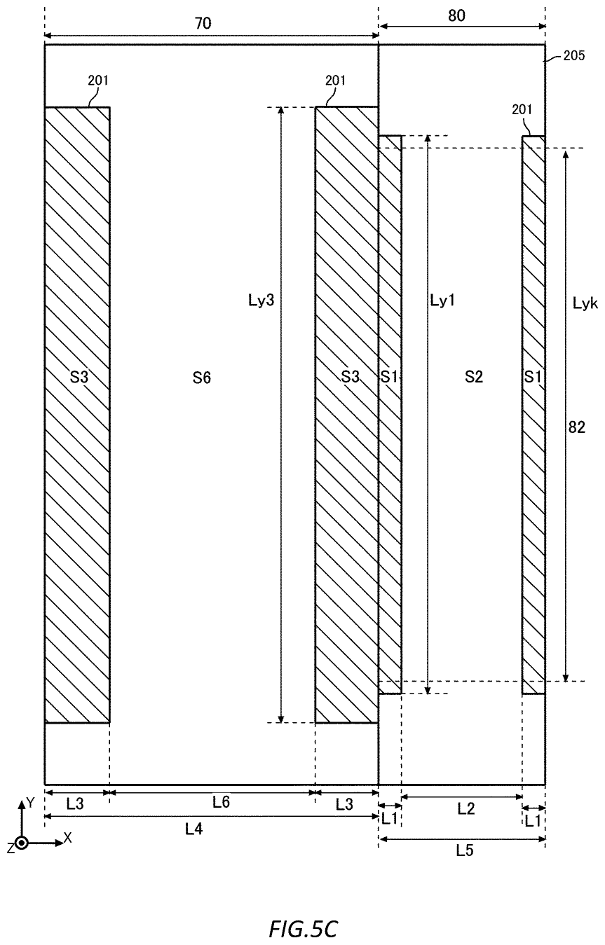

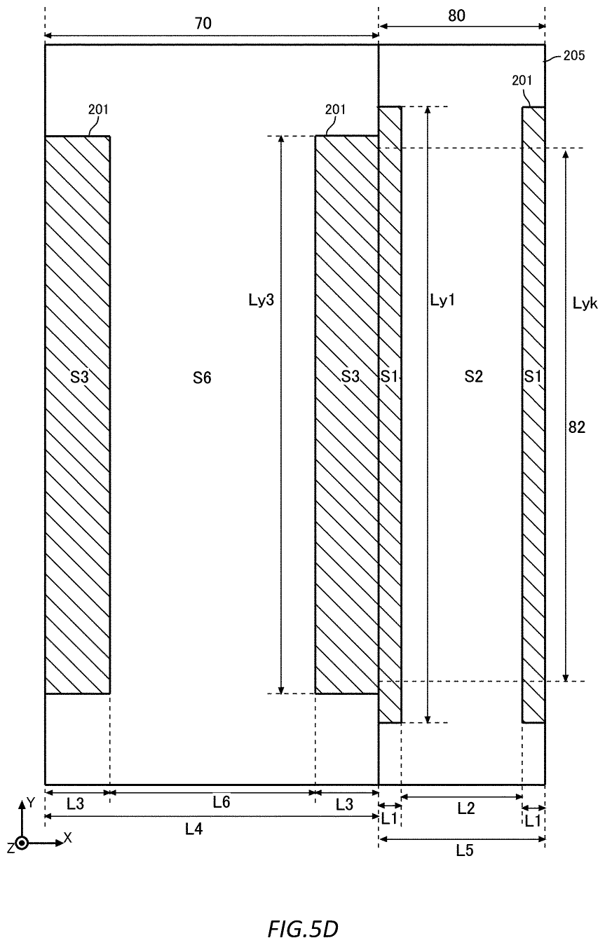

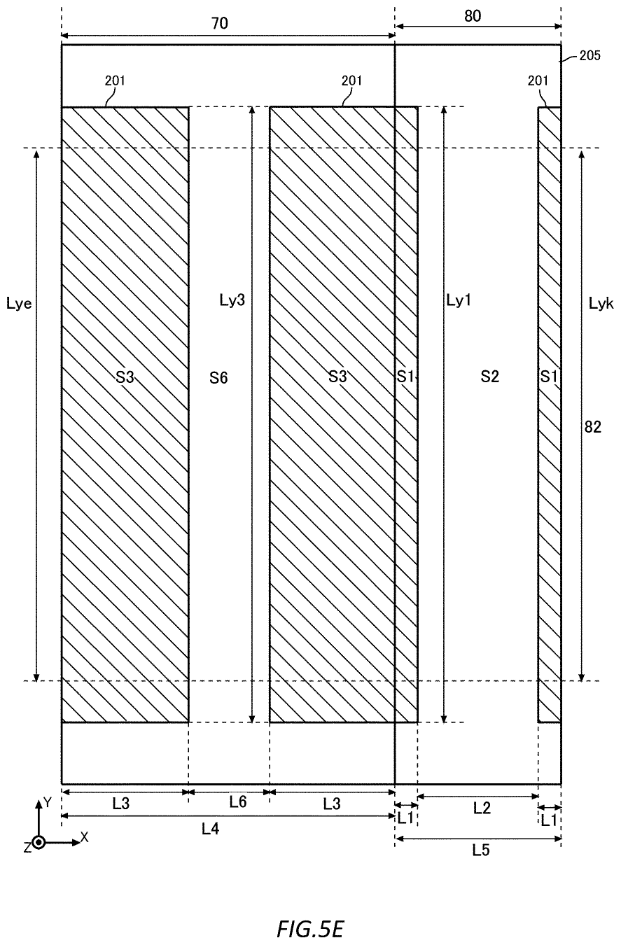

FIG. 5A illustrates a view showing an arrangement example of the first lifetime adjustment region 201 in the top view. FIG. 5A shows one transistor portion 70 and one diode portion 80 arranged in the X axis direction. Although omitted in FIG. 5A, the transistor portion 70 may be sandwiched between two diode portions 80 in the X axis direction, and the diode portion 80 may be sandwiched between two transistor portions 70 in the X axis direction.

In FIG. 5A, a range in which the first lifetime adjustment region 201 is provided is indicated by hatching with diagonal lines. In the top view, the area of the first lifetime adjustment region 201 provided in one diode portion 80 is defined as a first area S1. The area of a region of one diode portion 80 where the first lifetime adjustment region 201 is not provided in the top view is defined as a second area S2. In the top view, the area of the first lifetime adjustment region 201 provided in one transistor portion 70 is defined as a third area S3. The area of a region of one transistor portion 70 where the first lifetime adjustment region 201 is not provided in the top view is defined as a sixth area S6.

In the top view, the length of the cathode region 82 in the Y axis direction is denoted by Lyk. In the top view, the length of the cathode region 82 in the X axis direction is the same as the fifth length L5. In the top view, the length, in the Y axis direction, of the first lifetime adjustment region 201 in the diode portion 80 is denoted by Ly1. In the top view, the length, in the Y axis direction, of the first lifetime adjustment region 201 in the transistor portion 70 is denoted by Ly3. In this example, the length Ly1 and the length Ly3 are equal. In the top view, a distance between the base regions 14-e at both end portions of the transistor portion 70 is denoted by Lye. The distance Lye may be larger than, equal to, or shorter than the length Lyk. The distance Lye may be larger than, equal to, or shorter than the length Ly1. The distance Lye may be larger than, equal to, or shorter than the length Ly3.

In the top view, the length of the contact hole 54 in the Y axis direction is denoted by Lyh. The length Lyh may be shorter than the distance Lye. The length Lyh may be shorter than, equal to, or longer than the length Lyk. The length Lyh in this example is longer than the length Lyk. The length Lyh may be shorter than, equal to, or longer than the length Ly1. The length Lyh in this example is shorter than the length Ly1. The length Lyh may be shorter than, equal to, or longer than the length Ly3. The length Lyh in this example is shorter than the length Ly3. Also in another example below, a relationship between Lyh and another length and distance is similar.

As shown in FIG. 5A, when a plurality of first lifetime adjustment regions 201 are provided in one diode portion 80, the first area S1 is the total area of the plurality of first lifetime adjustment regions 201. Similarly, when a plurality of first lifetime adjustment regions 201 are provided in one transistor portion 70, the third area S3 is the total area of the plurality of first lifetime adjustment regions 201. In addition, when a plurality of first lifetime adjustment regions 201 are provided in one diode portion 80, the first length L1 described in FIG. 4A is the total length of the plurality of first lifetime adjustment regions 201. Similarly, when a plurality of first lifetime adjustment regions 201 are provided in one transistor portion 70, the third length L3 described in FIG. 4A is the total length of the plurality of first lifetime adjustment regions 201.

The first area S1 may be 0. That is, the first lifetime adjustment region 201 may not be provided in the diode portion 80. With this configuration, the leakage current flowing through the emitter electrode 52 can be reduced.

The first area S1 is smaller than the second area S2. That is, the first area S1 is smaller than a half of the area (S1+S2) of the diode portion 80. With this configuration, the leakage current flowing through the emitter electrode 52 can be reduced. The first area S1 may be 50% or less, 25% or less, 10% or less, or 5% or less of the second area S2.

The first area S1 may be 40% or less of the area (S1+S2) of the diode portion 80. The first area S1 may be 20% or less or 10% or less of the area (S1+S2) of the diode portion 80.

The first area S1 may be smaller than the third area S3. The first area S1 may be 50% or less, 25% or less, 10% or less, or 5% or less of the third area S3.

The total value of the third areas S3 in one transistor portion 70 is smaller than the sixth area S6. That is, the total value of the third areas S3 is smaller than half of the area (S3+S6) of the transistor portion 70. With this configuration, the leakage current flowing through the emitter electrode 52 can be reduced, and the saturation voltage of the transistor portion 70 can be reduced. The total value of the third areas S3 may be 50% or less, 25% or less, 10% or less, or 5% or less of the sixth area S6. One third areas S3 may be 25% or less, 10% or less, or 5% or less of the sixth area S6.

The total value of the third areas S3 may be 40% or less of the area (S3+S6) of the transistor portion 70. The total value of the third areas S3 may be 20% or less, or 10% or less of the area (S3+S6) of the transistor portion 70.

The sixth length L6 of the transistor portion 70 may be larger than the fifth length L5 of the diode portion 80. The sixth length L6 may be 1.5 times or more, 1.7 times or more, or 2 times or more the fifth length L5. The sixth area S6 may be larger than the area (S1+S2) of the diode portion 80. The sixth area S6 may be 1.5 times or more, 1.7 times or more, or 2 times or more the area (S1+S2) of the diode portion 80.

In addition, when the magnitudes of the fourth length L4 and the fifth length L5 are determined, it is also noted that snapback (negative resistance) is prevented from occurring in the current-voltage waveform of the transistor portion 70. In the reverse-conducting IGBT, when the transistor portion 70 is turned on, electrons are implanted into the drift region 18 from channels of electrons formed in a plurality of gate trench portions 40 formed on the upper surface 21 side. The implanted electrons flow from the drift region 18 to the cathode region 82 in contact with the collector electrode 24 formed on the lower surface 23 side via the buffer region 20 having a smaller resistance than the drift region 18. At this time, a resistance value along a path from the lower end of the channel of the gate trench portion 40 to the cathode region 82 is calculated. In the path of electrons having the lowest path resistance value along the path of electrons, when a voltage drop value obtained by multiplying an electron current and a path resistance value becomes larger than a built-in voltage Vbi of a pn junction between the buffer region 20 and the collector region 22, holes are implanted from the collector region 22 into the buffer region 20 and the drift region 18. On the other hand, when the path resistance value is relatively small, a large amount of electron current is required for the voltage drop value to exceed the built-in voltage Vbi. For this purpose, a collector-emitter voltage Vce needs to be increased. When Vce at this time is higher than the built-in voltage Vbi, snapback (negative resistance) occurs in the current-voltage waveform of the transistor portion 70. In order to suppress the occurrence of snapback, it is only required to increase the path resistance value so that the voltage drop value exceeds the built-in voltage Vbi with the electron current flowing at the collector-emitter voltage Vce sufficiently smaller than the built-in voltage Vbi.

In order to increase the path resistance value, as an example, it is only required to determine the shape of the transistor portion 70 in the Y axis direction or the X axis direction so that the path resistance value along the shortest path of electrons from the bottom surface of the gate trench portion 40 to the cathode region 82 exceeds the built-in voltage Vbi at a sufficiently small collector-emitter voltage Vce. For example, the half value of the fourth length L4 may be 100 μm or more. The third length L3 may be in the above-described range. The length Ly3 may be longer than the distance Lye. As a result, the shortest path of electrons can be lengthened, and snapback can be suppressed. In addition, since the path resistance value in the shortest path can be increased by allowing the shortest path of electrons to pass through the first lifetime adjustment region 201, snapback can be suppressed. As described above, it is possible to prevent the electron current from leaking to the diode portion 80 and to prevent the snapback (negative resistance) from occurring in the current-voltage waveform of the transistor portion 70.

The first lifetime adjustment region 201 may be provided in a range wider than that of the cathode region 82 in the Y axis direction, may be provided in the same range as that of the cathode region 82, or may be provided in a range narrower than that of the cathode region 82. The first area S1 and the second area S2 may be the area of a region overlapping with the cathode region 82, or may be the area of the diode portion 80 including the extension region 81 described in FIG. 1. As the third area S3, an area within the same range in the Y axis direction as that of the first area S1 and the second area S2 is used.

FIG. 5B illustrates a modification of the arrangement of the first lifetime adjustment regions 201 in the top view. The modification of FIG. 5B is different from the example of FIG. 5A in that the regions where the first lifetime adjustment regions 201 are not formed are regularly arranged in the Y axis direction. In the example of FIG. 5B, the regions where the first lifetime adjustment regions 201 are formed and the regions where the first lifetime adjustment regions are not formed are alternately arranged in the Y axis direction. Other aspects may be the same as in FIG. 5A.

The length in the Y axis direction of the region where the first lifetime adjustment region 201 is formed is denoted as Lya, and the length in the Y axis direction of the region where the first lifetime adjustment region 201 is not formed is denoted as Lyb. Lya may be larger than Lyb. Lyb may be 10% or less of the diffusion length of the carrier. With this configuration, an effect of reducing leakage current may be obtained while maintaining the lifetime reduction effect.

The length Lyc in the Y axis direction of the first lifetime adjustment region 201 arranged at the most end portion in the Y axis direction may be longer than the length Lya in the Y axis direction of the other first lifetime adjustment regions 201. With this configuration, the holes flowing into the cathode region 82 from the outside of the cathode region 82 in the Y axis direction can be reduced, and the concentration of carriers on the end portion of the cathode region 82 can be suppressed.

FIG. 5C illustrates a modification of the arrangement of the first lifetime adjustment regions 201 in the top view. In the modification of FIG. 5C, the length Ly3 in the Y axis direction of the first lifetime adjustment region 201 in the transistor portion 70 is longer than the length Ly1 in the Y axis direction of the first lifetime adjustment region 201 in the diode portion 80. In the example of FIG. 5C, the holes flowing into the cathode region 82 of the adjacent diode portion 80 from the outside of the transistor portion 70 in the Y axis direction can be reduced by the first lifetime adjustment region 201 of the transistor portion 70, and the concentration of carriers on the end portion of the cathode region 82 can be suppressed. Both the length Ly1 and the length Ly3 may be longer than the length Lyk of the cathode region 82 in the Y axis direction.

FIG. 5D illustrates a modification of the arrangement of the first lifetime adjustment regions 201 in the top view. In the modification of FIG. 5D, the length Ly1 in the Y axis direction of the first lifetime adjustment region 201 in the diode portion 80 is longer than the length Ly3 in the Y axis direction of the first lifetime adjustment region 201 in the transistor portion 70. The length Ly3 in the Y axis direction of the first lifetime adjustment region 201 in the transistor portion 70 of the example of FIG. 5D may be longer than the length Lyk in the Y axis direction of the cathode region 82. With this configuration, the holes flowing into the cathode region 82 of the adjacent diode portion 80 from the outside of the transistor portion 70 in the Y axis direction can be reduced by the first lifetime adjustment region 201 of the diode portion 80, and the concentration of carriers on the end portion of the cathode region 82 can be suppressed.

In each example, such as FIG. 5C or 5D, the features of FIG. 5B may be combined. In other words, the first lifetime adjustment regions 201 in each example may be continuously arranged in the Y axis direction as in the example of FIG. 5A, or may be discretely arranged as in the example of FIG. 5B.

FIG. 5E illustrates a view showing another arrangement example of the first lifetime adjustment region 201 in the top view. The semiconductor device 100 of this example is different from the example described in FIG. 5A in the arrangement of the first lifetime adjustment region 201 in the transistor portion 70. Other structures are similar to those in any of the examples described herein. The first lifetime adjustment region 201 of this example is provided in a wider range than that of the example described in FIG. 5A in the X axis direction of the transistor portion 70. Also in this example, it is possible to reduce the influence of the holes implanted from the contact region 15 of the transistor portion 70 on the diode portion 80.

The transistor portion 70 and the diode portion 80 are shortened in the fourth length L4 and the fifth length L5 and arranged repeatedly, so that it is possible to improve heat dissipation at the time of conduction for each, and it is possible to suppress a temperature rise. Since the portion into which many holes are implanted from the contact region 15 of the transistor portion 70 increases, the first lifetime adjustment region 201 may be provided in a wide portion of the transistor portion 70, and the ratio of the third length L3 to the fourth length L4 may increase. At this time, the leakage current flowing through the emitter electrode 52 can be reduced by reducing the ratio of the first length L1 of the diode portion 80 to the fifth length L5. In addition, the leakage current flowing through the emitter electrode 52 can be reduced particularly by making the first length L1 of the diode portion 80 smaller than the third length L3 of the transistor portion 70.

The total value of the third lengths L3 in the transistor portion 70 may be smaller than the length (fourth length L4) of the transistor portion 70 in the X axis direction. The total value of the third lengths L3 may be 50% or more, 70% or more, or 90% or more of the fourth length L4.

The total value of the third areas S3 in one transistor portion 70 may be larger than the sixth area S6. That is, the total value of the third areas S3 is larger than half of the area of the transistor portion 70. The total value of the third areas S3 may be 1 time or more, 1.25 times or more, 1.5 times or more, or 2 times or more the sixth area S6. One third area S3 may be 50% or more, 62.5% or more, or 75% or more of the sixth area S6.

The total value of the third areas S3 may be 50% or more of the area (S3+S6) of the transistor portion 70. The total value of the third areas S3 may be 80% or more, or 90% or more of the area (S3+S6) of the transistor portion 70.

The sixth length L6 of the transistor portion 70 may be shorter than the fifth length L5 of the diode portion 80. The sixth length L6 may be 1 time or less, 0.9 times or less, or 0.8 times or more the fifth length L5. The sixth area S6 may be smaller than the area (S1+S2) of the diode portion 80. The sixth area S6 may be 1 time or less, 0.9 times or more, or 0.8 times or more the area (S1+S2) of the diode portion 80.

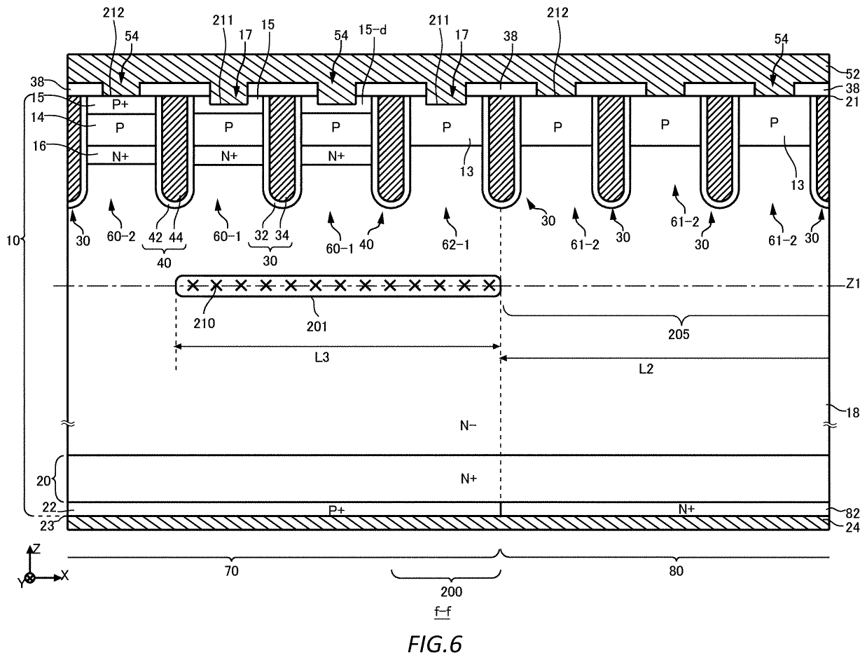

FIG. 6 illustrates a view showing another example of the cross section f-f in FIG. 2. This example is different from the examples shown in FIGS. 4A and 5A to 5E in that the first lifetime adjustment region 201 is not provided in the diode portion 80 (that is, the first length L1 is 0). Other structures are similar to those of any of the aspects described in FIGS. 4A and 5A to 5E.

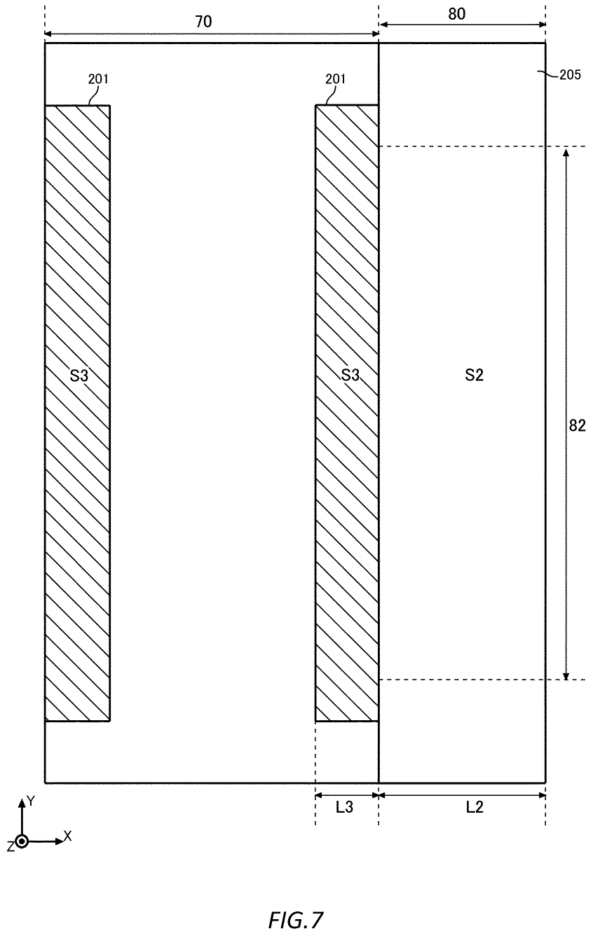

FIG. 7 illustrates a view showing another arrangement example of the first lifetime adjustment region 201 in the top view. This example is different from the example shown in FIGS. 4A and 5A to 5E in that the first lifetime adjustment region 201 is not provided in the diode portion 80 (that is, the first area S1 is 0). Other structures are similar to those of any of the aspects described in FIGS. 4A and 5A to 5E.

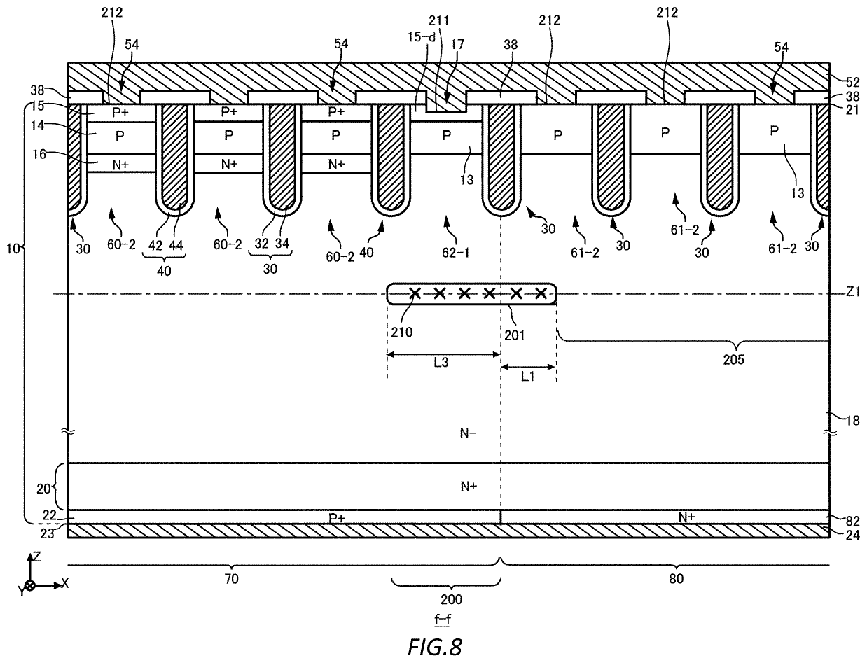

FIG. 8 illustrates a view showing another example of the cross section f-f in FIG. 2. The semiconductor device 100 of this example is different from the example described in FIGS. 1 to 7 in the arrangement of the first lifetime adjustment region 201 in the X axis direction. The first depth position in this example is provided at a position deeper than the second depth position with respect to the upper surface 21 of the semiconductor substrate 10. Other structures are similar to those of the examples described in FIGS. 1 to 7.

The first lifetime adjustment region 201 of this example is arranged below the mesa portion 62 of the boundary region 200, and is not arranged in the transistor portion 70 other than the boundary region 200. In the mesa portion 62 of this example, the contact region 15 is arranged similarly to the mesa portion 61. The contact region 15 and the anode region 13 may be alternately arranged on the upper surface of the mesa portion 62. Alternatively, all the contact regions 15 may be formed on the upper surface of the mesa portion 62. The first lifetime adjustment region 201 may or may not be arranged in the diode portion 80.

When the boundary region 200 has a plurality of mesa portions 62, the first lifetime adjustment region 201 may be arranged below the mesa portion 62 arranged closest to the diode portion 80. The first lifetime adjustment region 201 may be arranged also below another mesa portion 62 or may be arranged also below all the mesa portions 62.

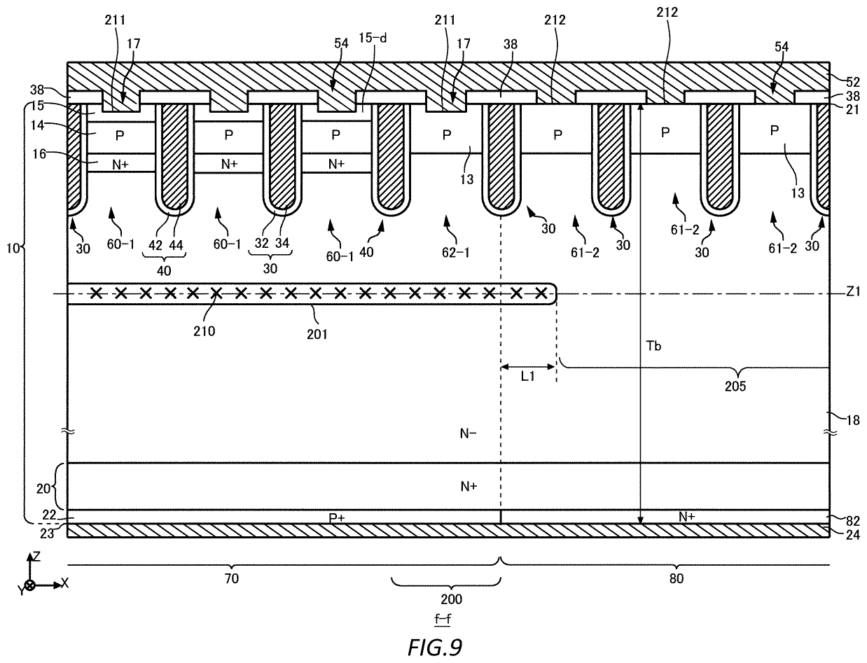

FIG. 9 illustrates a view showing another example of the cross section f-f in FIG. 2. The semiconductor device 100 of this example is different from the example described in FIGS. 1 to 7 in the arrangement of the first lifetime adjustment region 201 in the transistor portion 70. The first depth position in this example is provided at a position deeper than the second depth position with respect to the upper surface 21 of the semiconductor substrate 10. Other structures are similar to those of the examples described in FIGS. 1 to 7. The first lifetime adjustment region 201 of this example is provided in the entire transistor portion 70 in the X axis direction. With this configuration, the turn-off time of the transistor portion 70 can be reduced, and a high-speed operation can be performed. Also in this example, it is possible to reduce the influence of the holes implanted from the contact region 15 of the transistor portion 70 on the diode portion 80.

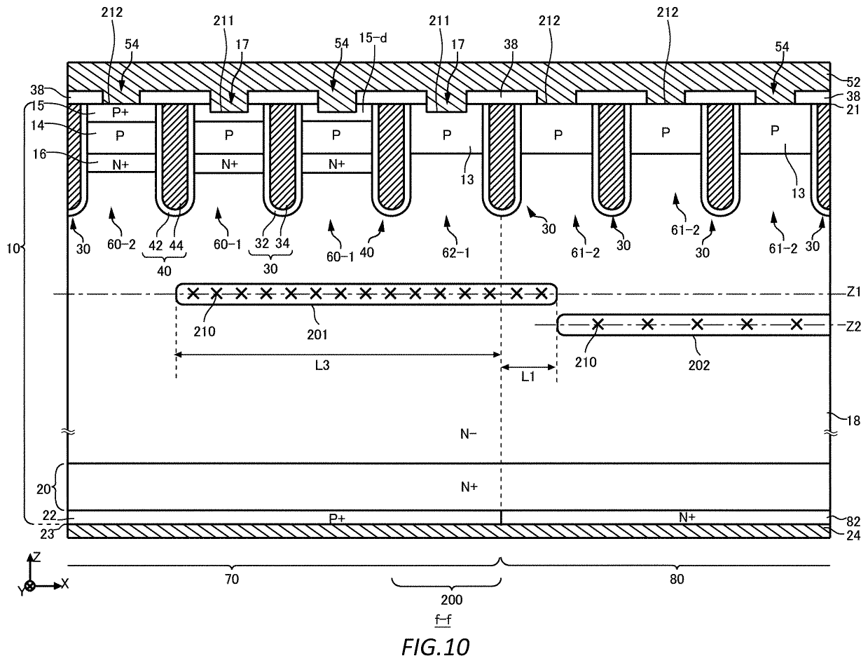

FIG. 10 illustrates a view showing another example of the cross section f-f in FIG. 2. The semiconductor device 100 of this example has a second lifetime adjustment region 202. The structure other than the second lifetime adjustment region 202 is similar to any other aspect described in the present specification. Note that the first depth position in this example is provided at a position deeper than the second depth position with respect to the upper surface 21 of the semiconductor substrate 10.

The second lifetime adjustment region 202 is provided at the second depth Z2 on the upper surface 21 side of the semiconductor substrate 10 in the diode portion 80. The second depth Z2 may be the same as or different from the first depth Z1. In FIG. 10, the second lifetime adjustment region 202 is provided at a position (lower surface 23 side) deeper than that of the first lifetime adjustment region 201, but may be provided at a position (upper surface 21 side) shallower than the first lifetime adjustment region 201.

The second lifetime adjustment region 202 is provided at a position not overlapping with the first lifetime adjustment region 201 in the top view. The second lifetime adjustment region 202 may be provided in the whole of the region, which does not overlap with the first lifetime adjustment region 201 in the top view, of the diode portion 80.

The second defect density, which is the density of lattice defects in the second lifetime adjustment region 202, is smaller than the first defect density of the first lifetime adjustment region 201. The second defect density may be 50% or less, 25% or less, 10% or less, or 5% or less of the first defect density. The second defect density may be 1% or more of the first defect density.

By providing the second lifetime adjustment region 202, the carrier lifetime of the diode portion 80 can be adjusted overall. In addition, the leakage current can be suppressed by reducing the second defect density of the second lifetime adjustment region 202. The second lifetime adjustment region 202 is arranged relatively away from the contact region 15 of the transistor portion 70. For this reason, even if the second defect density of the second lifetime adjustment region 202 is reduced, the influence of the holes implanted from the contact region 15 of the transistor portion 70 on the lifetime is small.

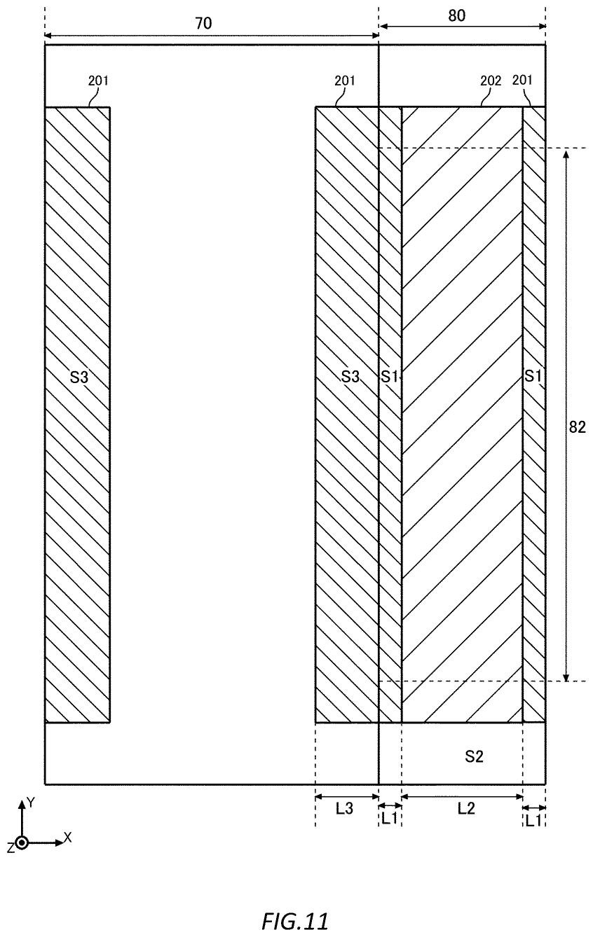

FIG. 11 illustrates a view showing an arrangement example of the second lifetime adjustment region 202 in the top view. The second lifetime adjustment region 202 is arranged in a region not overlapping with the first lifetime adjustment region 201.

In the X axis direction, the second lifetime adjustment region 202 may be in contact with the first lifetime adjustment region 201. In the X axis direction, the second lifetime adjustment region 202 may be arranged in the whole of the region where the first lifetime adjustment region 201 is not provided.

In the example of FIG. 11, the second lifetime adjustment region 202 is not in contact with the first lifetime adjustment region 201 in the Y axis direction, but the second lifetime adjustment region 202 may be in contact with the first lifetime adjustment region 201 in the Y axis direction. The second lifetime adjustment region 202 may be arranged so as to sandwich the first lifetime adjustment region 201 in the Y axis direction. The second lifetime adjustment region 202 may be arranged in the whole of the region of the diode portion 80 where the first lifetime adjustment region 201 is not provided in the top view.

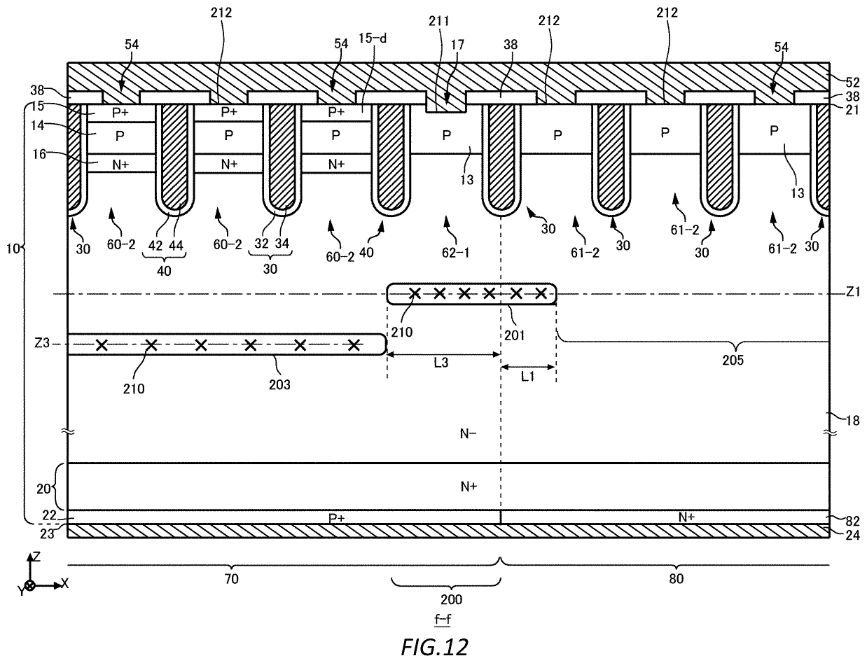

FIG. 12 illustrates a view showing another example of the cross section f-f in FIG. 2. The semiconductor device 100 of this example includes a third lifetime adjustment region 203. The structure other than the third lifetime adjustment region 203 is similar to any other aspect described in the present specification. The diode portion 80 in the example of FIG. 12 does not have the second lifetime adjustment region 202, but the diode portion 80 may have the second lifetime adjustment region 202. Note that the first depth position in this example is provided at a position deeper than the second depth position with respect to the upper surface 21 of the semiconductor substrate 10.

The third lifetime adjustment region 203 is provided at a third depth Z3 on the upper surface 21 side of the semiconductor substrate 10 in the transistor portion 70. The third depth Z3 may be the same as or different from the first depth Z1. The third depth Z3 may be the same as or different from the second depth Z2. In FIG. 12, the third lifetime adjustment region 203 is provided at a position (lower surface 23 side) deeper than that of the first lifetime adjustment region 201, but may be provided at a position (upper surface 21 side) shallower than the first lifetime adjustment region 201.

The third lifetime adjustment region 203 is provided at a position not overlapping with the first lifetime adjustment region 201 in the top view. The third lifetime adjustment region 203 is arranged farther away from the diode portion 80 than the first lifetime adjustment region 201. The third lifetime adjustment region 203 may be provided in the whole of the region, which does not overlap with the first lifetime adjustment region 201 in the top view, of the transistor portion 70.

The third defect density, which is the density of lattice defects in the third lifetime adjustment region 203, is smaller than the first defect density of the first lifetime adjustment region 201. The third defect density may be 50% or less, 25% or less, 10% or less, or 5% or less of the first defect density. The third defect density may be 1% or more of the first defect density. The third defect density may be the same as the second defect density of the second lifetime adjustment region 202, smaller than the second defect density, or larger than the second defect density.

By providing the third lifetime adjustment region 203, the carrier lifetime of the transistor portion 70 can be adjusted overall. In addition, the leakage current can be suppressed by reducing the third defect density of the third lifetime adjustment region 203. The third lifetime adjustment region 203 is arranged relatively away from the diode portion 80. For this reason, even if the third defect density of the third lifetime adjustment region 203 is reduced, the influence on the diode portion 80 is small.

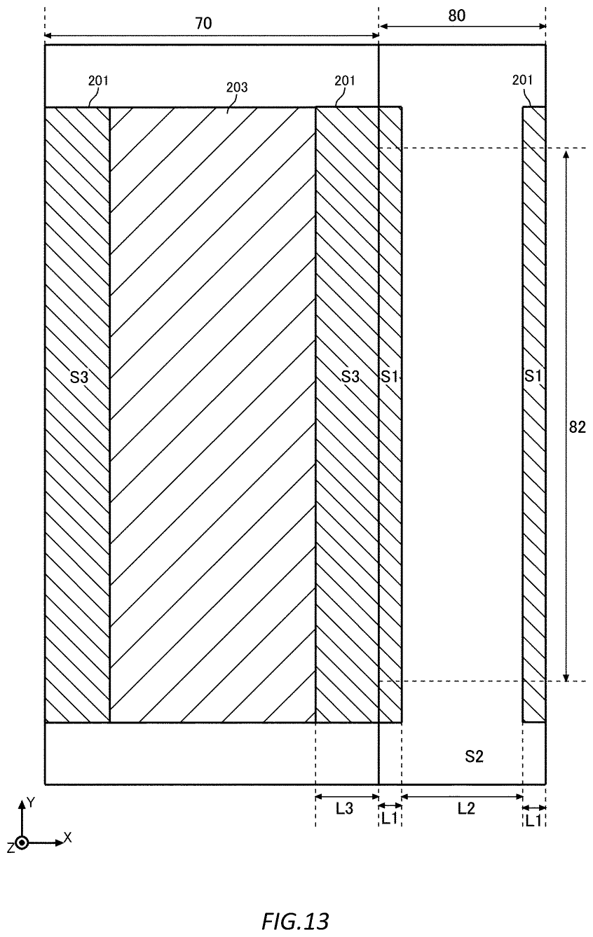

FIG. 13 illustrates a view showing an arrangement example of the third lifetime adjustment region 203 in the top view. The third lifetime adjustment region 203 is arranged in a region not overlapping with the first lifetime adjustment region 201 in the transistor portion 70.

In the X axis direction, the third lifetime adjustment region 203 may be in contact with the first lifetime adjustment region 201. In the X axis direction, the third lifetime adjustment region 203 may be arranged in the whole of the region where the first lifetime adjustment region 201 is not provided.

In the example of FIG. 13, the third lifetime adjustment region 203 is not in contact with the first lifetime adjustment region 201 in the Y axis direction, but the third lifetime adjustment region 203 may be in contact with the first lifetime adjustment region 201 in the Y axis direction. The third lifetime adjustment region 203 may be arranged so as to sandwich the first lifetime adjustment region 201 in the Y axis direction. The third lifetime adjustment region 203 may be arranged in the whole of the region of the transistor portion 70 where the first lifetime adjustment region 201 is not provided in the top view.

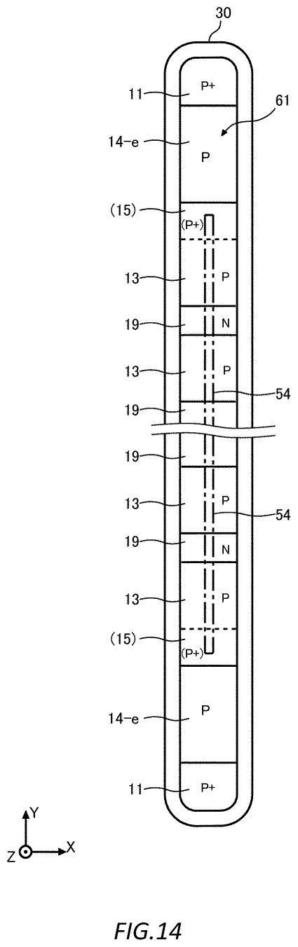

FIG. 14 illustrates a view showing another example of the mesa portion 61 of the diode portion 80. The anode region 13 and a dummy anode region 19 of the N type are provided on the upper surface of the mesa portion 61 of this example. The dummy anode region 19 and the anode region 13 are arranged side by side in the Y axis direction. In the example of FIG. 14, the dummy anode regions 19 and the anode regions 13 are alternately arranged between two base regions 14-e. The dummy anode regions 19 and the anode regions 13 may be alternately arranged twice or more along the Y axis direction. As shown in parentheses in FIG. 14, the contact region 15 may be provided between the base region 14-e and the anode region 13. In this example, the contact region 15 is not provided between the base region 14-e and the anode region 13. The doping concentrations of the base region 14-e and the anode region 13 may be the same, and the doping concentration of the anode region 13 may be lower than the doping concentration of the base region 14-e. In this example, the doping concentration of the anode region 13 is lower than the doping concentration of the base region 14-e.

The dummy anode region 19 may be in Schottky contact with the emitter electrode 52 via the contact hole 54, or may be in ohmic contact therewith. The dummy anode region 19 may be provided on the upper surface 21 side with respect to the anode region 13 in the depth direction. The anode region 13 may be exposed on the upper surface 21 so as to be sandwiched between the dummy anode regions 19 adjacent in the Y axis direction. The anode region 13 may be in ohmic contact with the emitter electrode 52 via the contact hole 54, or may be in Schottky contact therewith. In this example, the dummy anode region 19 is in Schottky contact with the emitter electrode 52, and the anode region 13 is in ohmic contact with the emitter electrode 52. A plug electrode (not shown) which is in contact with both the emitter electrode 52 and the semiconductor substrate 10 may be formed in the contact hole 54. In the contact hole 54, a barrier metal or silicide in contact with both the emitter electrode 52 or the plug electrode and the semiconductor substrate 10 may be formed. In the anode region 13 or the contact region 15 of the diode portion 80 and the transistor portion 70, a plug region (not shown) of a high concentration and the P type may be formed in a region in contact with the barrier metal. The doping concentration of the plug region of the P type may be higher than the doping concentration of the contact region 15. In the anode region 13, the plug region may be formed over the entire region in contact with the barrier metal, or may be formed discretely in a part thereof. A trench contact (not shown) may be formed in the contact hole 54.

According to this example, the area of the anode region 13 on the upper surface of the mesa portion 61 of the diode portion 80 is reduced. For this reason, the implantation of holes from the anode region 13 of the mesa portion 61 can be suppressed. Therefore, characteristics such as the reverse recovery time and the reverse recovery loss of the diode portion 80 can be adjusted without providing the first lifetime adjustment region 201 in at least a part of the diode portion 80.

In the diode portion 80, the mesa portion 61 in which the first lifetime adjustment region 201 is not arranged may have the dummy anode region 19 as shown in FIG. 14. In the diode portion 80, the mesa portion 61 in which the first lifetime adjustment region 201 is arranged may have the dummy anode region 19 as shown in FIG. 14, and may not have the dummy anode region 19. The mesa portion 61 in which the second lifetime adjustment region 202 is arranged may have the dummy anode region 19 as shown in FIG. 14, and may not have the dummy anode region 19.

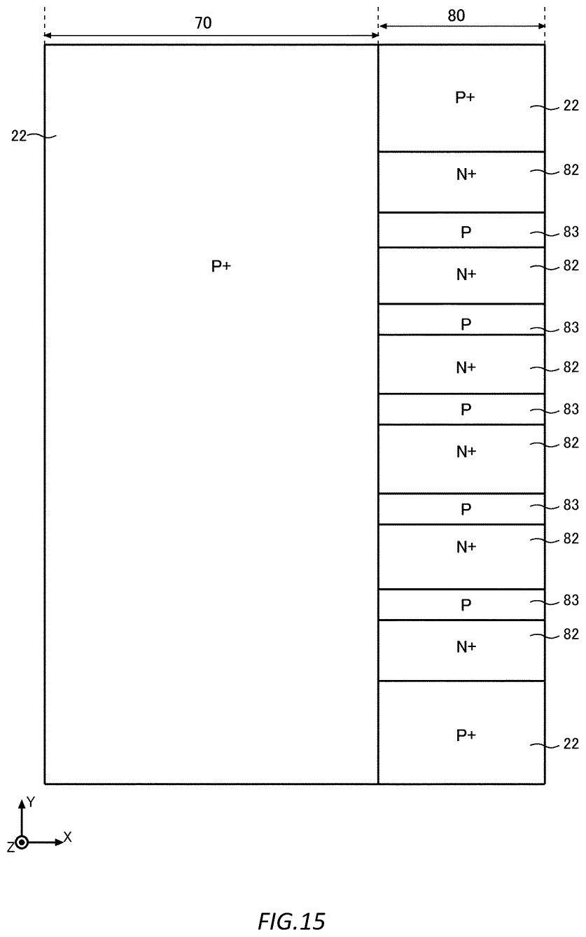

FIG. 15 illustrates a view showing a structure example of the lower surface 23 of the semiconductor substrate 10. FIG. 15 shows the structure of one transistor portion 70 and one diode portion 80. In the transistor portion 70, the collector region 22 is arranged on the lower surface 23 of the semiconductor substrate 10.

The diode portion 80 of this example has the cathode region 82 and a dummy cathode region 83 provided on the lower surface 23 of the semiconductor substrate 10. The cathode region 82 is similar to the cathode region 82 described in FIGS. 1 to 14.

The dummy cathode region 83 is a P type region arranged between the cathode regions 82 in a second direction different from the first direction (the X axis direction in this example). The second direction in this example is the Y axis direction, but is not limited thereto. The second direction is a direction not parallel to the first direction in the XY plane.

In the diode portion 80 of this example, the cathode region 82 and the dummy cathode region 83 are arranged side by side in the Y axis direction. In the example of FIG. 15, the cathode regions 82 and the dummy cathode regions 83 are alternately arranged twice or more along the Y axis direction.

According to this example, the area of the cathode region 82 of the diode portion 80 is reduced. For this reason, the implantation of electrons from the cathode region 82 of the diode portion 80 is suppressed. By suppressing the implantation of electrons into the drift region 18, the implantation of holes from the anode region 13 is suppressed. Therefore, characteristics such as the reverse recovery time and the reverse recovery loss of the diode portion 80 can be adjusted without providing the first lifetime adjustment region 201 in at least a part of the diode portion 80.

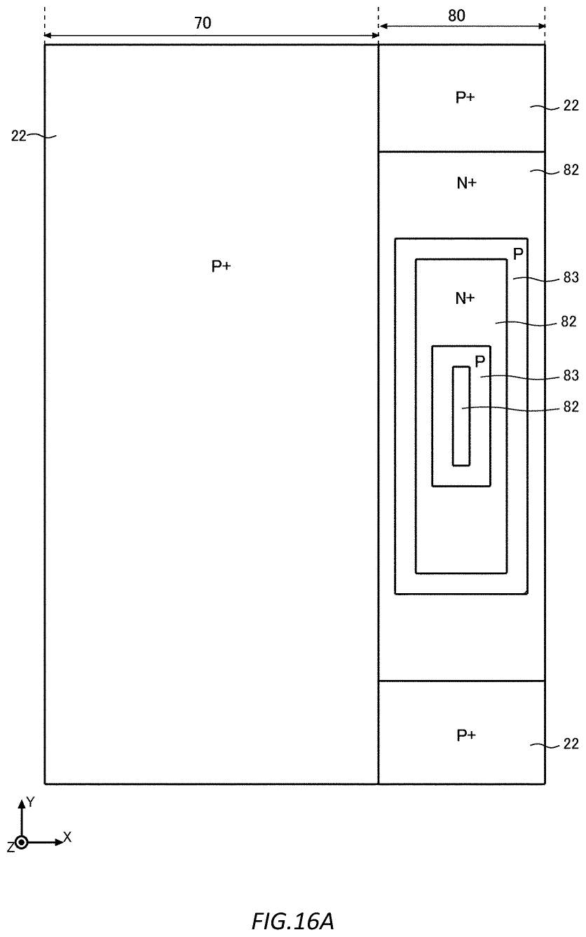

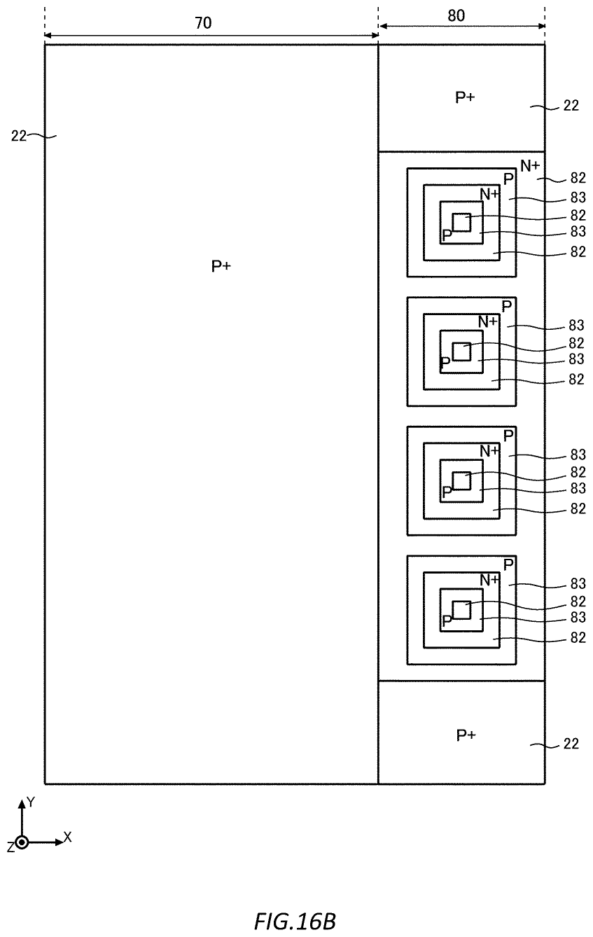

FIG. 16A illustrates a view showing a structure example of the lower surface 23 of the semiconductor substrate 10. In FIG. 16A, the arrangement of the dummy cathode regions 83 is different from the example of FIG. 15. Other structures are similar to those in the example of FIG. 15.

The dummy cathode region 83 of this example encloses a predetermined region in the top view. The cathode region 82 may be arranged in the region enclosed by the dummy cathode region 83. As shown in FIG. 16A, one or more dummy cathode regions 83 and one or more cathode regions 82 may be alternately arranged concentrically. The shapes of the dummy cathode region 83 and the cathode region 82 in the top view may be a circle, an ellipse, or an oval, or may be a rectangular frame shape. Also in this example, the implantation of electrons from the cathode region 82 of the diode portion 80 is suppressed. Therefore, characteristics such as the reverse recovery time and the reverse recovery loss of the diode portion 80 can be adjusted without providing the first lifetime adjustment region 201 in at least a part of the diode portion 80.

FIG. 16B illustrates a view showing another structure example of the lower surface 23 of the semiconductor substrate 10. In this example, a plurality of concentric structures of the dummy cathode region 83 and the cathode region 82 shown in FIG. 16A are arranged along the Y axis direction. In each concentric structure, the width in the X axis direction and the width in the Y axis direction of the cathode region 82 may be equal to the width in the X axis direction and the width in the Y axis direction of the dummy cathode region 83. In addition, the width of the cathode region 82 in the X axis direction may be equal to the width of the cathode region in the Y axis direction, and the width of the dummy cathode region 83 in the X axis direction may be equal to the width of the dummy cathode region in the Y axis direction.

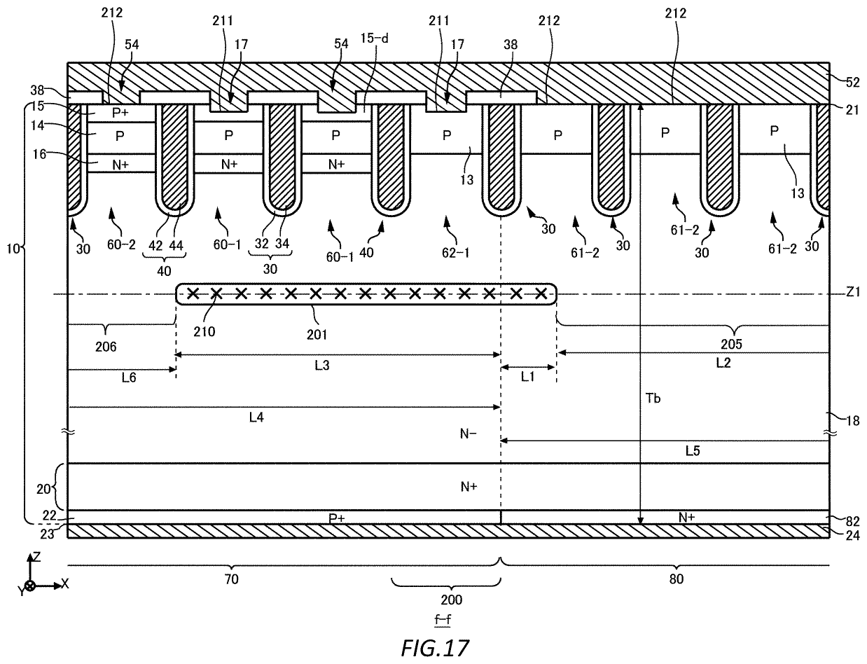

FIG. 17 illustrates another view showing another example of the mesa portion 61 of the diode portion 80. The first depth position in this example is provided at a position deeper than the second depth position with respect to the upper surface 21 of the semiconductor substrate 10. The interlayer dielectric film 38 is not provided on the upper surface of the diode portion 80 of this example. However, as shown in FIG. 17, the interlayer dielectric film 38 may be provided in a part of the mesa portion 61 closest to the transistor portion 70. When the interlayer dielectric film 38 and the contact hole 54 are provided, in order to facilitate embedding in the narrow contact hole 54, in the contact hole, the plug electrode 251 formed by embedding tungsten or the like is provided, and the barrier metal 252 is provided in a layer below the plug electrode. Then, in order to sufficiently reduce a contact resistance between the barrier metal 252 and the P type region of the mesa portions 60 and 61, a plug region of a high concentration is provided. In this example, since the interlayer dielectric film 38 is not provided in the diode portion 80 and the contact hole 54 is not provided, the plug electrode 251 and the barrier metal 252 become unnecessary. The anode region 13 of this example can be in contact with the upper layer of the emitter electrode 52 formed of aluminum or the like, that is, the upper portion 250 with a sufficiently low contact resistance without providing the plug region. In addition, in the diode portion 80, the dummy conductive portion 34 may be connected to the emitter electrode 52. For this reason, the upper portion of the dummy conductive portion 34 may be in contact with the emitter electrode 52 without providing the interlayer dielectric film 38 above the dummy trench portion 30. As described above, the interlayer dielectric film 38 is not provided in the diode portion 80, so that it is not necessary to provide the plug region of a high concentration in the diode portion 80, and the implantation of holes can be suppressed. Therefore, characteristics such as the reverse recovery time and the reverse recovery loss of the diode portion 80 can be adjusted without providing the first lifetime adjustment region 201 in at least a part of the diode portion 80.

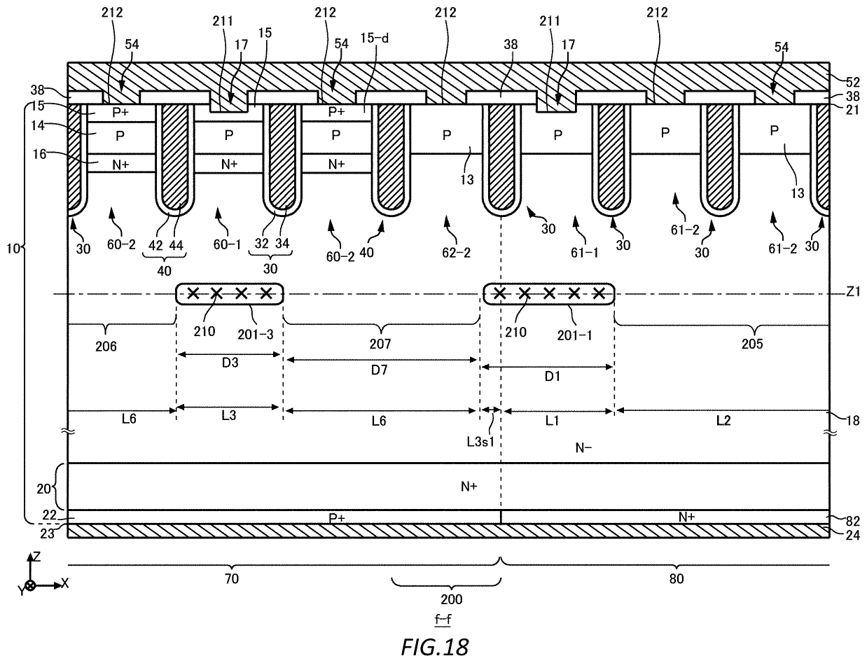

FIG. 18 illustrates a view showing another example of the cross section f-f in FIG. 2. The first depth position in this example is provided at a position deeper than the second depth position with respect to the upper surface 21 of the semiconductor substrate 10. In this example, the first lifetime adjustment region 201-3 of the transistor portion 70 and the first lifetime adjustment region 201-1 of the diode portion 80 are separated from each other. Other structures are similar to any of the aspects described in FIGS. 1 to 17. The area of the first lifetime adjustment region 201 can be reduced by arranging a separation region 207, which separates the first lifetime adjustment region 201, between the first lifetime adjustment region 201-3 and the first lifetime adjustment region 201-1. With this configuration, the leakage current can be reduced.

The first lifetime adjustment region 201-1 includes the portion provided in the diode portion 80. The first lifetime adjustment region 201-1 may or may not include the portion provided in the transistor portion 70. The first lifetime adjustment region 201-3 includes the portion provided in the transistor portion 70. The first lifetime adjustment region 201-3 may or may not include the portion provided in the diode portion 80. The portion of the first lifetime adjustment region 201 in which the portion provided in the diode portion 80 is larger than the portion provided in the transistor portion 70 may be set as the first lifetime adjustment region 201-1. The portion of the first lifetime adjustment region 201 in which the portion provided in the transistor portion 70 is larger than the portion provided in the diode portion 80 may be set as the first lifetime adjustment region 201-3. The size of the portion may be compared in terms of a width in the X axis direction, or may be compared in terms of an area in the top view.

The first lifetime adjustment region 201-1 and the first lifetime adjustment region 201-3 in this example are aligned in the X axis direction. As shown in FIG. 18, the first lifetime adjustment region 201-1 and the first lifetime adjustment region 201-3 may be separated in the transistor portion 70. In other words, the separation region 207 which separates the first lifetime adjustment region 201-1 and the first lifetime adjustment region 201-3 may be provided in the transistor portion 70. The separation region 207 is a region where the first lifetime adjustment region 201 is not provided. The separation region 207 may have the same carrier lifetime as that of the region 206 and may have the same carrier lifetime as that of the region 205. In another example, the first lifetime adjustment region 201-1 and the first lifetime adjustment region 201-3 may be separated in the diode portion 80. In other words, the separation region 207 may be provided in the diode portion 80. In another example, the first lifetime adjustment region 201-1 and the first lifetime adjustment region 201-3 may be separated in both of the transistor portion 70 and the diode portion 80. In other words, the separation region 207 may be provided over both of the transistor portion 70 and the diode portion 80.

The first lifetime adjustment region 201-3 may include the region arranged below the contact region 15. Above one first lifetime adjustment region 201-3, only one contact region 15 may be arranged, or a plurality of the contact regions 15 may be arranged. By arranging the first lifetime adjustment region 201-3 below the contact region 15, the lifetime of the holes can be adjusted efficiently. In addition, the leakage current can be reduced by separating the first lifetime adjustment region 201.

The first lifetime adjustment region 201-3 is not necessarily arranged in at least part of a region below the contact region 15, which is closest to the diode portion 80, among the contact regions 15. In other words, the separation region 207 may be arranged in at least part of the region below the contact region 15. With this configuration, in the portion, which is close to the boundary region 200, of the transistor portion 70, the transistor portion 70 can be turned favorably without being disturbed by the first lifetime adjustment region 201. The separation region 207 may be arranged in the entire region below the contact region 15. The separation region 207 in FIG. 18 is also provided in the boundary region 200. In another example, the first lifetime adjustment region 201-3 may be provided below the contact region 15 closest to the diode portion 80, and the separation region 207 may be provided in the boundary region 200.

A first width D1 of the first lifetime adjustment region 201-1 in the first direction (in this example, the X axis direction) may be larger than a third width D3 of any first lifetime adjustment region 201-3 in the X axis direction. The first width D1 of the first lifetime adjustment region 201-1 in the X axis direction may be larger than the third width D3, in the X axis direction, of the first lifetime adjustment region 201-3 closest to the diode portion 80. The leakage current in the transistor portion 70 can be reduced by reducing the first lifetime adjustment region 201-3.

The first width D1 of the first lifetime adjustment region 201-1 in the X axis direction may be smaller than the third width D3 of any first lifetime adjustment regions 201-3 in the X axis direction. The first width D1 of the first lifetime adjustment region 201-1 in the X axis direction may be smaller than the third width D3, in the X axis direction, of the first lifetime adjustment region 201-3 closest to the diode portion 80. The leakage current in the diode portion 80 can be reduced by reducing the first lifetime adjustment region 201-1.

The length of the separation region 207 in the X axis direction is determined as a seventh width D7. The first width D1 may be smaller than the sum of the seventh width D7 and the third width D3. The seventh width D7 may be larger than the third width D3, or and may be larger than the first width D1. The leakage current can be reduced by increasing the seventh width D7 of the separation region 207. Alternatively, the seventh width D7 may be smaller than the third width D3, or may be smaller than the first width D1. Even in this case, by providing the separation region 207, the leakage current can be reduced compared to a case where the separation region 207 is not provided.

In the example of FIG. 18, the first lifetime adjustment region 201-1 has a portion provided in the transistor portion 70. In the first lifetime adjustment region 201-1, the length, in the X axis direction, of the portion provided in the transistor portion 70 is defined as a third protruding length L3s1. In addition, in the first lifetime adjustment region 201-1, the length, in the X axis direction, of the portion provided in the diode portion 80 is defined as the first length L1. The first width D1, in the X axis direction, of the first lifetime adjustment region 201-1 in this example is the sum (L1+L3s1) of the first length L1 and the third protruding length L3s1.

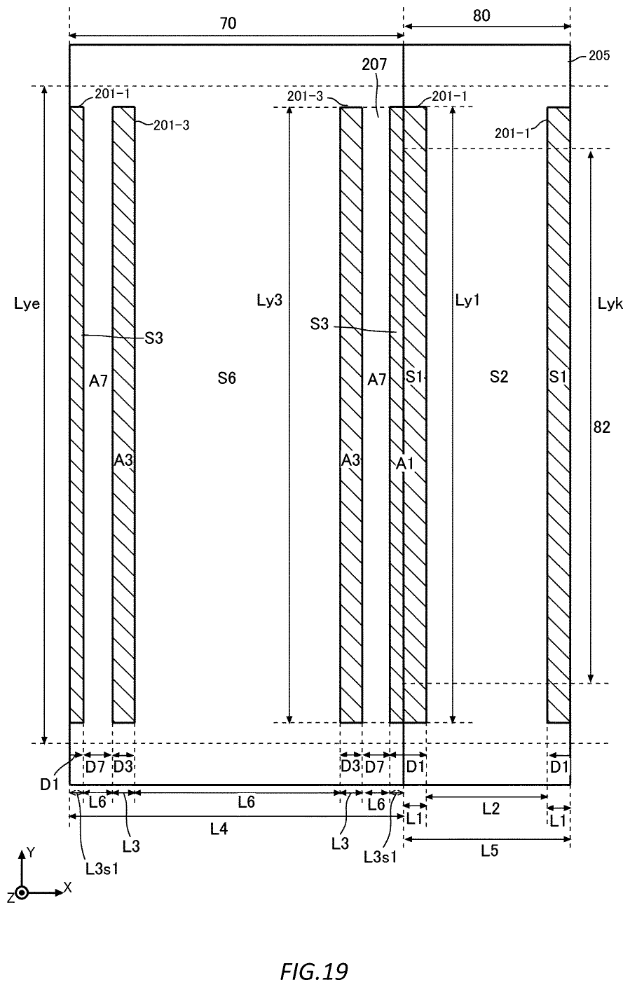

FIG. 19 illustrates a view showing an arrangement example of the first lifetime adjustment region 201-1 and the first lifetime adjustment region 201-3 in the top view. This example is different from the examples described in FIGS. 1 to 17 in that the first lifetime adjustment region 201-1 of the diode portion 80 and the first lifetime adjustment region 201-3 of the transistor portion 70 are separated from each other. Other structures are similar to any of the aspects described in FIGS. 1 to 17.

In this example, the area of one first lifetime adjustment region 201-1 is defined as a first total area A1, the area of one first lifetime adjustment region 201-3 is defined as a third total area A3, and the area of the separation region 207 is defined as a seventh total area A7. In this example, the positions of both ends of the first lifetime adjustment region 201-1 in the Y axis direction are identical to those of the first lifetime adjustment region 201-3. The positions of both ends of the separation region 207 of the Y axis direction are set to be the same as those of the first lifetime adjustment region 201. In this example, the positions of both ends of the first lifetime adjustment region 201-1 in the Y axis direction may not be identical to those of the first lifetime adjustment region 201-3. In this case, the positions of both ends of the separation region 207 in the Y axis direction are set to be the same as the positions of both ends of the first lifetime adjustment region, which has a smaller length in the Y axis direction, among the first lifetime adjustment region 201-1 and the first lifetime adjustment region 201-3.

The first total area A1 may be larger than the third total area A3 in any first lifetime adjustment region 201-3. The first total area A1 may be larger than the third total area A3 of the first lifetime adjustment region 201-3 closest to the diode portion 80. The leakage current in the transistor portion 70 can be reduced by reducing the first lifetime adjustment region 201-3.

The first total area A1 may be smaller than the third total area A3 in any first lifetime adjustment region 201-3. The first total area A1 may be smaller than the third total area A3 of the first lifetime adjustment region 201-3 closest to the diode portion 80. The leakage current in the diode portion 80 can be reduced by reducing the first lifetime adjustment region 201-1.

In this example, the first total area A1 may be smaller than the sum of the seventh total area A7 and the third total area A3. The seventh total area A7 may be larger than the third total area A3, or may be larger than the first total area A1. The leakage current can be reduced by increasing the seventh total area A7 of the separation region 207. Alternatively, the seventh total area A7 may be smaller than the third total area A3, or may be smaller than the first total area A1. Even in this case, by providing the separation region 207, the leakage current can be reduced compared to a case where the separation region 207 is not provided.

The distance Lye in this example may be the same or different from any of the examples described in FIGS. 1 to 17. In the example of FIG. 19, the distance Lye is larger than any of the lengths Ly1 and Ly3.

The distance Lyk in this example may be the same or different from any of the examples described in FIGS. 1 to 17. In the example in FIG. 19, the distance Lyk is smaller than any of the lengths Ly1 and Ly3.

In addition, also in an example where the separation region 207 is provided in any region of the diode portion 80 and transistor portion 70, as described in FIGS. 1 to 17, the length of the first lifetime adjustment region 201 in the transistor portion 70 may be set as a part of the third length L3, the length of the first lifetime adjustment region 201 in the diode portion 80 may be set as a part of the first length L1, the length of the separation region 207 in the transistor portion 70 may be set as a part of the sixth length L6, and the length of the separation region 207 in the diode portion 80 may be a part of the second length L2.

In addition, the area of the first lifetime adjustment region 201 in the transistor portion 70 may be set as a part of the third area S3, the area of the first lifetime adjustment region 201 in the diode portion 80 may be set as a part of the first area S1, the area of the separation region 207 in the transistor portion 70 may be set as a part of the sixth area S6, and the area of the separation region 207 in the diode portion 80 may be set as a part of the second area S2. In the example of FIG. 18, the lengths of the first lifetime adjustment regions 201-3 and 201-1 in the transistor portion 70 may be set as a part of the third length L3, the length of the first lifetime adjustment region 201-1 in the diode portion 80 may be set as a part of the first length L1, and the length of the separation region 207 may be set as a part of the L6. In the example in FIG. 19, the areas of the first lifetime adjustment regions 201-3 and 201-1 in the transistor portion 70 may be set as a part of the third area S3, the area of the first lifetime adjustment region 201-1 in the diode portion 80 may be set as a part of the first area S1, and the area of the separation region 207 in the transistor portion 70 may be set as a part of the S6. At this time, the description, as given in FIGS. 1 to 17, regarding the length L1, L2, L3, L4, L5, L6 of each portion or the area S1, S2, S3, S4, S5, S6 of each portion is also applicable to the examples of FIG. 18 and subsequent drawings. Even when the separation region 207 is provided in the middle of any of the first lifetime adjustment regions 201 shown in FIGS. 1 to 17, and the first lifetime adjustment region 201 is divided into a plurality of regions, the above description regarding the length L1, L2, L3, L4, L5, L6 of each portion or the area S1, S2, S3, S4, S5, S6 of each portion may be applied.

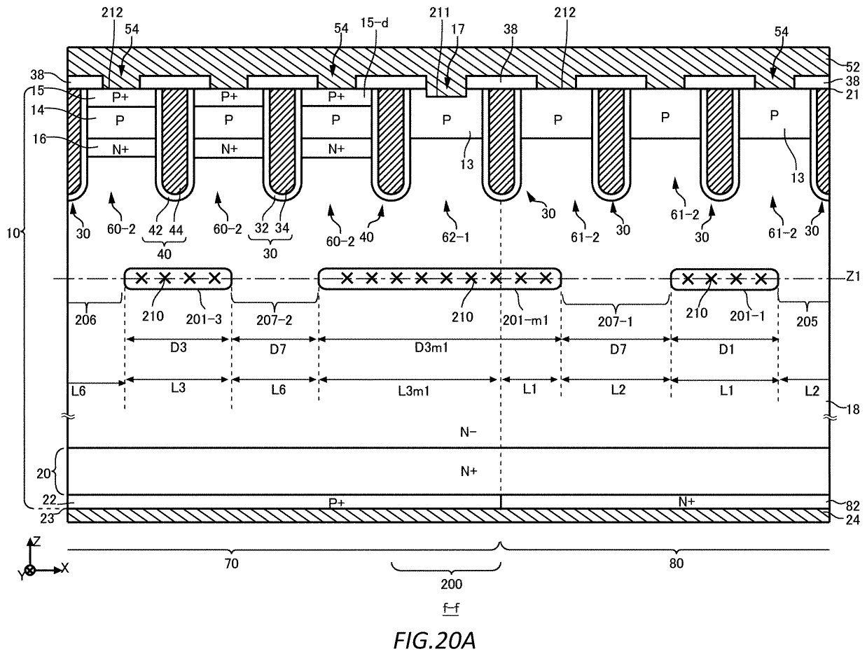

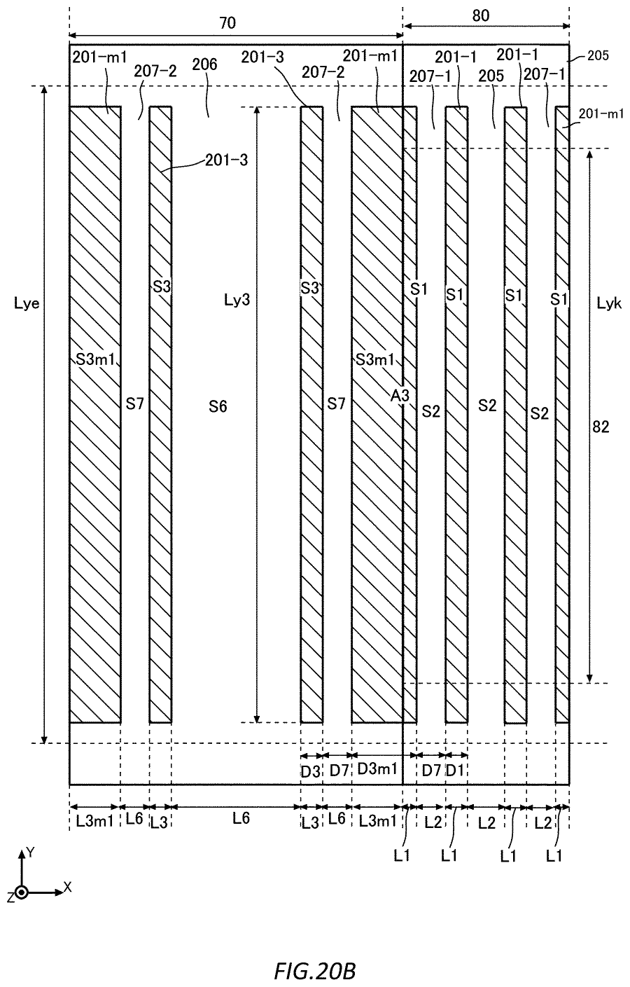

FIG. 20A illustrates a view showing another example of the cross section f-f in FIG. 2. The first depth position in this example is provided at a position deeper than the second depth position with respect to the upper surface 21 of the semiconductor substrate 10.

FIG. 20B illustrates a view showing an arrangement example of the first lifetime adjustment region 201 corresponding to FIG. 20A in the top view. This example is different from the examples described in FIGS. 1 to 19 in that a plurality of the separation regions 207-1 and 207-2, which separate the first lifetime adjustment region 201 into three portions 201-1, 201-3, and 201-m1 are provided. Other structures are similar to any of the aspects described in FIGS. 1 to 19. The area of the first lifetime adjustment region 201 can be reduced by arranging the plurality of the separation regions 207-1 and 207-2 which separate the first lifetime adjustment region 201 into three or more portions. With this configuration, the leakage current can be reduced.

In this example, the entire first lifetime adjustment region 201-3 is arranged in the transistor portion 70. The arrangement of the first lifetime adjustment region 201-3 may be similar to the examples described in FIGS. 1 to 19.

In this example, the entire first lifetime adjustment region 201-1 is arranged in the diode portion 80. The arrangement of the first lifetime adjustment region 201-1 may be similar to the examples described in FIGS. 1 to 19.

In this example, the first lifetime adjustment region 201-m1 has a portion arranged in the transistor portion 70 and a portion arranged in the diode portion 80. In the example of FIG. 20A, in the first lifetime adjustment region 201-m1, the portion arranged in the transistor portion 70 is larger than the portion arranged in the diode portion 80. In other words, the first lifetime adjustment region 201-m1 shown in FIG. 20A is an example of the first lifetime adjustment region 201-3. In another example, in the first lifetime adjustment region 201-m1, the portion arranged in the diode portion 80 may be larger than the portion arranged in the transistor portion 70. In this case, the first lifetime adjustment region 201-m1 is an example of the first lifetime adjustment region 201-1.

The separation region 207-1 is arranged between the first lifetime adjustment region 201-1 and the first lifetime adjustment region 201-m1. The separation region 207-1 may be arranged in the diode portion 80. The separation region 207-2 is arranged between the first lifetime adjustment region 201-3 and the first lifetime adjustment region 201-m1. The separation region 207-2 may be arranged in the transistor portion 70. The seventh width D7 of the separation region 207-1 in the X axis direction and the seventh width D7 of the separation region 207-2 in the X axis direction may be the same. In another example, in the separation region 207-1, the seventh width D7 in the X axis direction may be larger or may be smaller than that of the separation region 207-2.

In the example of FIG. 20A, the first lifetime adjustment region 201-m1 has a portion provided in the transistor portion 70 and a portion provided in the diode portion 80. In the first lifetime adjustment region 201-m1, the length, in the X axis direction, of the portion provided in the transistor portion 70 is defined as a third protruding length L3m1. In addition, in the first lifetime adjustment region 201-m1, the length, in the X axis direction, of the portion provided in the diode portion 80 is the first length L1. The third width D3m1, in the X axis direction, of the first lifetime adjustment region 201-m1 in this example is the sum (L1+L3m1) of the first length L1 and the third protruding length L3m1.

In the example of FIG. 20B, the first lifetime adjustment region 201-m1 has a portion provided in the transistor portion 70 and a portion provided in the diode portion 80. In the first lifetime adjustment region 201-m1, the area of the portion provided in the transistor portion 70 is defined as a third area S3m1. In addition, the area of the portion, which is provided in the diode portion 80, of the first lifetime adjustment region of 201-m1 is the first area S1. The third total area A3 of the first lifetime adjustment region 201-m1 of this example is the sum (S1+S3m1) of the first area S1 and the third area S3m1.

In another example, three or more separation regions 207 may be provided in the vicinity of one boundary region 200 of the transistor portion 70 and the diode portion 80. In other words, in the vicinity of the boundary region 200, the first lifetime adjustment region 201 may be divided into four or more portions. The vicinity of the boundary region 200 may refer to, for example, a range where a distance from the boundary region 200 in the X axis direction is smaller than half of the total width of the transistor portion 70 and the diode portion 80 in the X axis direction, or may refer to a range where the distance may be not more than ¼ of the total width.

As described above, in the examples of FIGS. 20A and 20B, the separation region 207-1 is provided in the diode portion 80, and the separation region 207-2 is provided in the transistor portion 70. The first lifetime adjustment region 201-1 is provided in the diode portion 80, the first lifetime adjustment region 201-3 is provided in the transistor portion 70, and the first lifetime adjustment region 201-m1 is provided over the transistor portion 70 and the diode portion 80. In a plurality of divided first lifetime adjustment regions 201-1, the first lifetime adjustment region 201-1 which is provided inside any one of the transistor portion 70 or the diode portion 80 may be regarded as the first lifetime adjustment region 201 of the transistor portion 70 or the diode portion 80. In the example in FIG. 20A, the first lifetime adjustment region 201-1 may be the first lifetime adjustment region 201 of the diode portion 80, the first lifetime adjustment region 201-3 may be a part of the first lifetime adjustment region 201 of the transistor portion 70, and the lengths thereof may be a part of the first width D1 and a part of the third width D3. The first lifetime adjustment region 201-m1 provided over the transistor portion 70 and the diode portion 80 may be regarded as the first lifetime adjustment region 201 of the transistor portion 70 or the diode portion 80 whichever has a relatively large width or a relatively large area. In the examples of FIGS. 20A and 20B, the portion, which is included in the transistor portion 70, of the first lifetime adjustment region 201-m1 is relatively large, and thus the first lifetime adjustment region 201-m1 may be regarded as a part of the first lifetime adjustment region 201-3 of the transistor portion 70. In the first lifetime adjustment region 201-m1, the third length L3m1 of the portion provided in the transistor portion 70 may be a part of the third width D3m1. The sum of the lengths of a plurality of divided separation regions 207 may be the seventh width D7. Also in the example in FIGS. 20A and 20B, the first total area A1, the third total area A3, and the seventh total area A7 may be defined similarly to the other examples. At this time, the width D1, D3, D7 of each portion and the total area A1, A3, A7 of each portion as described using FIGS. 18 and 19 may also be applied to the example in FIGS. 20A and 20B.

In addition, also in an example where there is a plurality of the separation regions 207, as described in FIGS. 1 to 17, the length of the first lifetime adjustment region 201 in the transistor portion 70 may be set as a part of the third length L3, the length of the first lifetime adjustment region 201 in the diode portion 80 may be set as a part of the first length L1, the length of the separation region 207 in the transistor portion 70 may be set as a part of the sixth length L6, and the length of the separation region 207 in the diode portion 80 may be a part of the second length L2. In addition, the area of the first lifetime adjustment region 201 in the transistor portion 70 may be set as a part of the third area S3, the area of the first lifetime adjustment region 201 in the diode portion 80 may be set as a part of the first area S1, the area of the separation region 207 in the transistor portion 70 may be set as a part of the sixth area S6, and the area of the separation region 207 in the diode portion 80 may be set as a part of the second area S2. In the example of FIG. 20A, the lengths of the first lifetime adjustment regions 201-3 and 201-m1 in the transistor portion 70 may be set as a part of the third length L3, the lengths of the first lifetime adjustment region 201-1 and 201-m1 in the diode portion 80 may be set as a part of the first length L1, the length of the separation region 207-1 may be set as a part of the L2, and the length of the separation region 207-2 may be set as a part of the L6. In the example of FIG. 20B, the areas of the first lifetime adjustment regions 201-3 and 201-m1 in the transistor portion 70 may be set as a part of the third area S3, the areas of the first lifetime adjustment region 201-1 and 201-m1 in the diode portion 80 may be set as a part of the first area S1, the area of the separation region 207-1 may be set as a part of the S2, and the area of the separation region 207-2 may be set as a part of the S6. At this time, the length L1, L2, L3, L4, L5, L6 of each portion or the area S1, S2, S3, S4, S5, S6 of each portion as described in FIGS. 1 to 17 may also be applied to the example in FIGS. 20A and 20B.

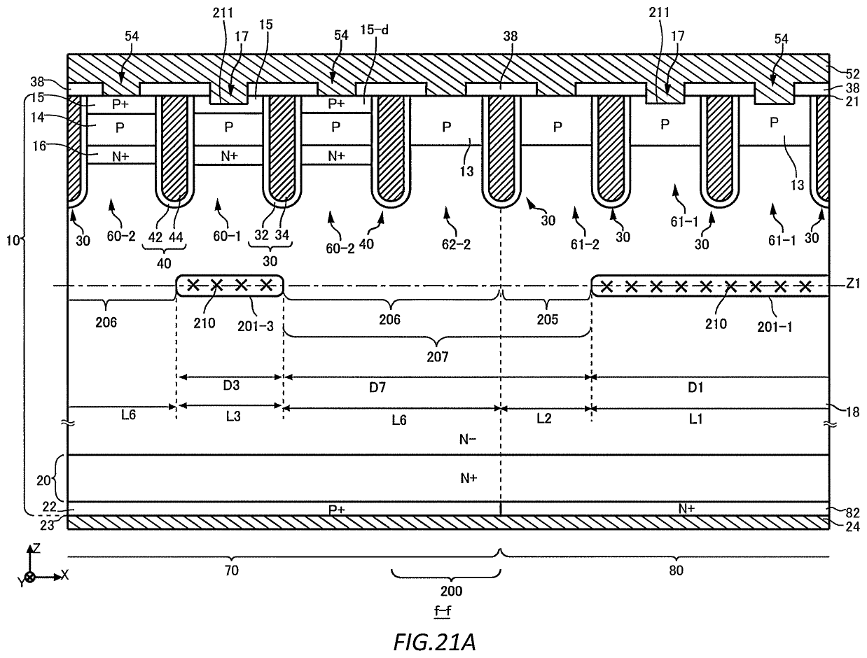

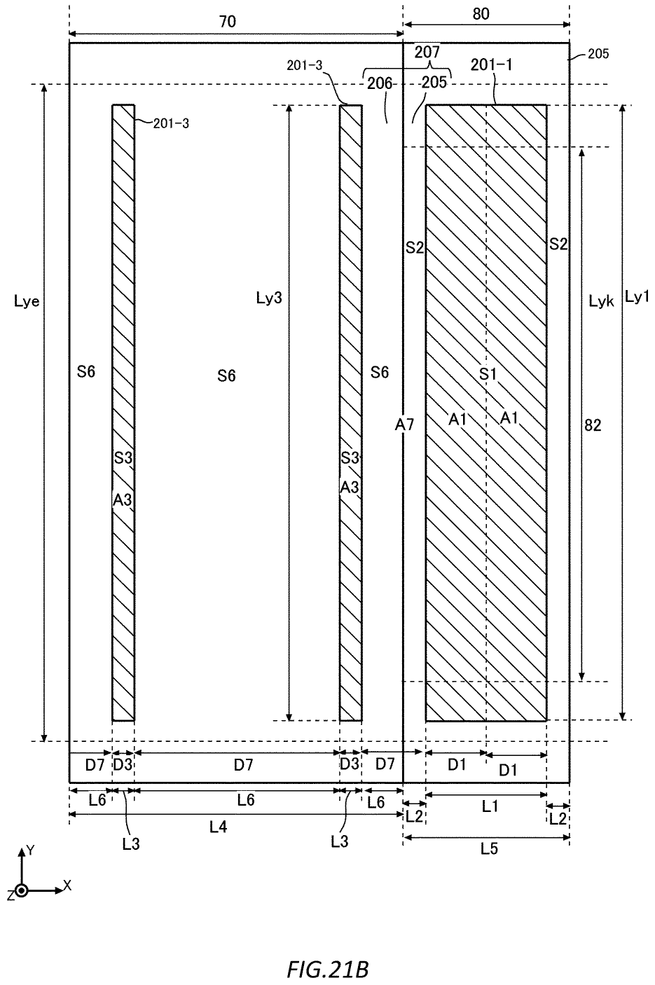

FIG. 21A illustrates a view showing another example of the cross section f-f in FIG. 2. The first depth position in this example is provided at a position deeper than the second depth position with respect to the upper surface 21 of the semiconductor substrate 10.

FIG. 21B illustrates a view showing an arrangement example of the first lifetime adjustment region 201 corresponding to FIG. 21A in the top view. This example is different from the example described in FIGS. 18 and 19 in that the separation region 207 is provided over the transistor portion 70 and the diode portion 80, and the first lifetime adjustment region 201-1 of the diode portion 80 is provided to the vicinity of the center of the diode portion 80 in the X axis direction. Other structures are similar to any of the aspects described in FIGS. 1 to 20B. The first lifetime adjustment regions 201-1 respectively extending from the vicinity of two transistor portions 70 which are opposed to each other with the diode portion 80 sandwiched therebetween may be connected at the center of the diode portion 80 to form one region. In this case, the first lifetime adjustment region 201-1 includes the center portion of the diode portion 80 in the X axis direction. Even in such cases, the area of the first lifetime adjustment region 201 can be reduced by arranging the separation region 207 which separates the first lifetime adjustment region 201 into a plurality of portions. With this configuration, the leakage current can be reduced.

The separation region 207, which is provided over the transistor portion 70 and the diode portion 80, has the region 206 provided in the transistor portion 70 and the region 205 provided in the diode portion 80. The region 206 may be larger, may be equal in size, or may be smaller than the region 205.

In another example, the separation region 207 may be provided on the transistor portion 70, and the first lifetime adjustment region 201-1 may be provided on the entire surface of the diode portion 80. The separation region 207 may be divided into two or more regions. The first lifetime adjustment region 201-3 may be provided to the vicinity of the center of the transistor portion 70, or the first lifetime adjustment regions 201-3 respectively extending from the vicinity of both diode portions 80 which are opposed to each other with the transistor portion 70 sandwiched therebetween may be connected at the center of the transistor portion 70 to form one region.

In the example of FIGS. 21A and 21B, the separation region 207 is provided over the transistor portion 70 and the diode portion 80. The first lifetime adjustment region 201-1 is provided in the diode portion 80, and the first lifetime adjustment region 201-3 is provided in the transistor portion 70. In this example, when the length of the separation region 207 is defined as the seventh width D7, the length of the first lifetime adjustment region 201-3 is defined as the third width D3, and in the length of the first lifetime adjustment region 201-1, a length to the center of the diode portion 80, that is, a half of the entire length is defined as the first width D1, the width D1, D3, D7 of each portion as described using FIGS. 18 and 19 may also be applied to this example. In addition, similarly, when the area of the separation region 207 is defined as the seventh total area A7, the area of the first lifetime adjustment region 201-3 is defined as the third total area A3, and in the first lifetime adjustment region 201-1, an area to the center of the diode portion 80, that is, a half of the total area is defined as the first total area A1, the total area A1, A3, A7 of each portion as described using FIGS. 18 and 19, may also be applied to this example.

In addition, also in an example where the first lifetime adjustment region 201-1 of the diode portion 80 is provided to the vicinity of the center of the diode portion 80, as described in FIGS. 1 to 17, the length of the first lifetime adjustment region 201 in the transistor portion 70 may be set as a part of the third length L3, the length of the first lifetime adjustment region 201 in the diode portion 80 may be set as a part of the first length L1, the length of the separation region 207 in the transistor portion 70 may be set as a part of the sixth length L6, and the length of the separation region 207 in the diode portion 80 may be a part of the second length L2. In addition, the area of the first lifetime adjustment region 201 in the transistor portion 70 may be set as a part of the third area S3, the area of the first lifetime adjustment region 201 in the diode portion 80 may be set as a part of the first area S1, the area of the separation region 207 in the transistor portion 70 may be set as a part of the sixth area S6, and the area of the separation region 207 in the diode portion 80 may be set as a part of the second area S2. In the example of FIG. 21A, the first lifetime adjustment region 201-3 may be set as a part of the third length L3, the first lifetime adjustment region 201-1 may be set as a part of the first length L1, and the length of the separation region 207 in the transistor portion 70 and the length of the separation region 207 in the diode portion 80 may be set as a part of the L6 and a part of the L2, respectively. In the example of FIG. 21B, the area of the first lifetime adjustment region 201-3 may be set as a part of the third area S3, the area of the first lifetime adjustment region 201-1 may be set as a part of the first area S1, and the area of the separation region 207 in the transistor portion 70 and the area of the separation region 207 in the diode portion 80 may be set as a part of the S6 and a part of the S2, respectively. At this time, the length L1, L2, L3, L4, L5, L6 of each portion or the area S1, S2, S3, S4, S5, S6 of each portion as described in FIGS. 1 to 17 may also be applied to this example.

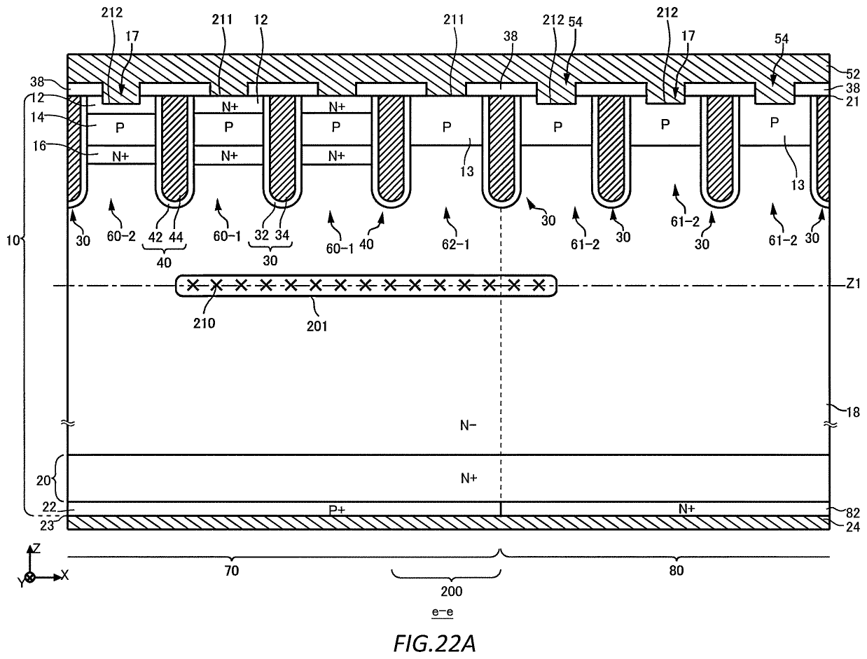

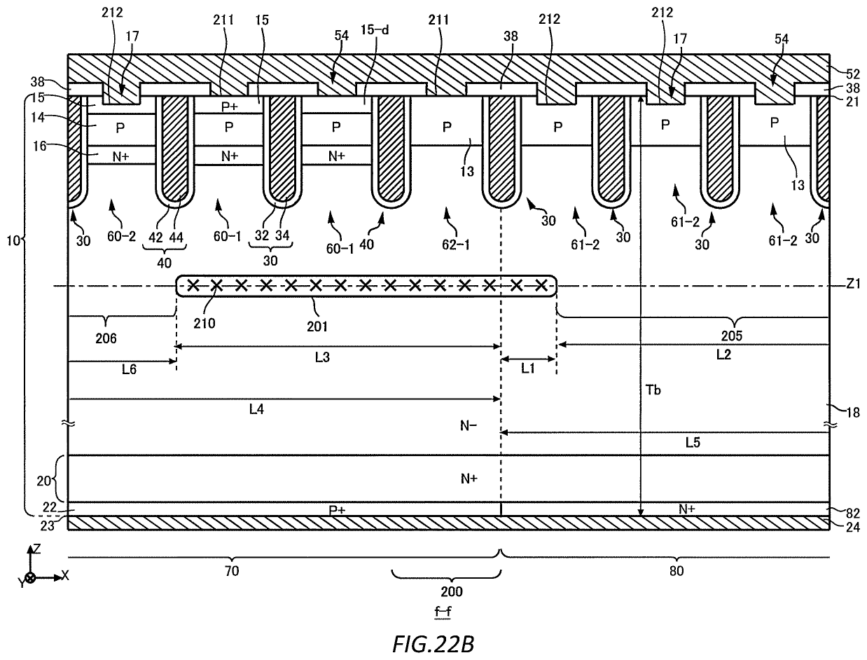

FIG. 22A illustrates a view showing another example of the cross section e-e in FIG. 2. The first depth position in this example is provided at a position shallower than the second depth position with respect to the upper surface 21 of the semiconductor substrate 10. Other structures are similar to those of the semiconductor device 100 of any example in the present specification. In the example shown in FIG. 22 A, structures other than the first depth position and the second depth position are similar to those in the example of FIG. 3A.

FIG. 22B illustrates a view showing an example of an cross section f-f in FIG. 2. The first depth position in this example is provided at a position shallower than the second depth position with respect to the upper surface 21 of the semiconductor substrate 10. Other structures are similar to those in the example of FIG. 4A. In addition, the structure is different from the structure shown in FIG. 22A in that the contact region 15 is provided instead of the emitter region 12 in the structure of the cross section e-e shown in FIG. 22A. Other structures are similar to those in the example of FIG. 22A.

In the examples of FIGS. 22A and 22B, the first depth position is provided at a position shallower than the second depth position with respect to the upper surface 21 of the semiconductor substrate 10. At least one second contact portion 212 includes the trench contact portion 17 in which the emitter electrode 52 is provided inside the semiconductor substrate 10. The second depth position in this example is the depth position of the bottom surface of the trench contact portion 17 provided in the second contact portion 212.

The first depth position in this example is the depth position of the first contact portion 211 provided on the upper surface 21 of the semiconductor substrate 10. The lower end of the first contact portion 211 of this example is arranged on the upper surface 21 of the semiconductor substrate 10. The first contact portion 211 may be a part of the upper surface 21 of the semiconductor substrate 10. In the examples of FIGS. 22 A and 22B, the second contact portions 212 of all the second mesa portions are provided with the trench contact portions 17, and the first contact portions 211 of all the first mesa portions are arranged on the upper surface 21.

By providing the trench contact portion 17 in the second contact portion 212, holes can be easily extracted in the second mesa portion, and the withstand capability can be increased. When the trench contact portion 17 is provided in the first contact portion 211, the amount of the barrier metal 252 increases, and hydrogen is occluded, so that a threshold may be lowered without the recovery of the level of the gate dielectric film 42 due to the provision of the first lifetime adjustment region 201, but the lowering of the threshold can be suppressed by forming the first contact portion 211 shallowly. Since the first mesa portion is provided with the first lifetime adjustment region 201, latch-up can be suppressed without providing the trench contact portion 17 or the like to promote hole extraction.

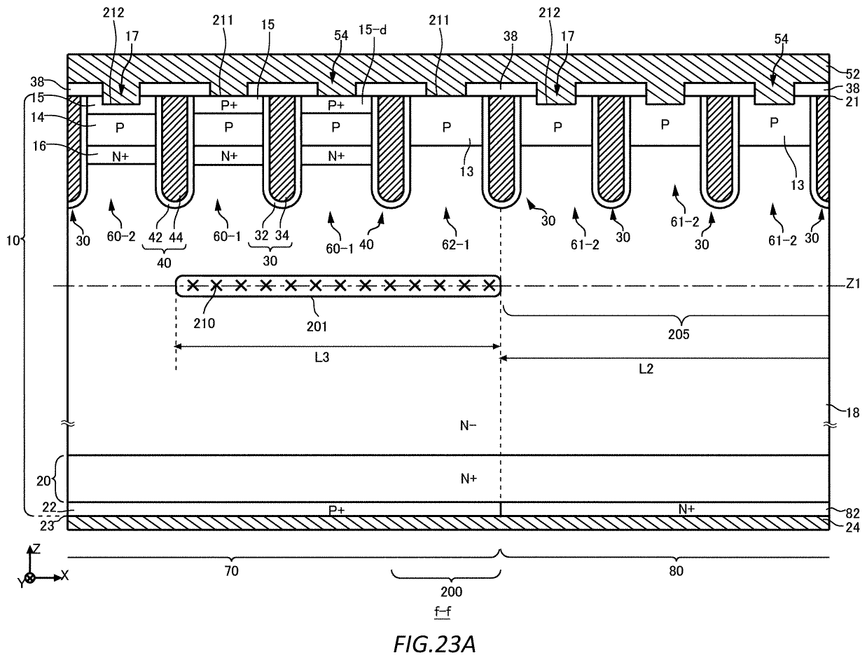

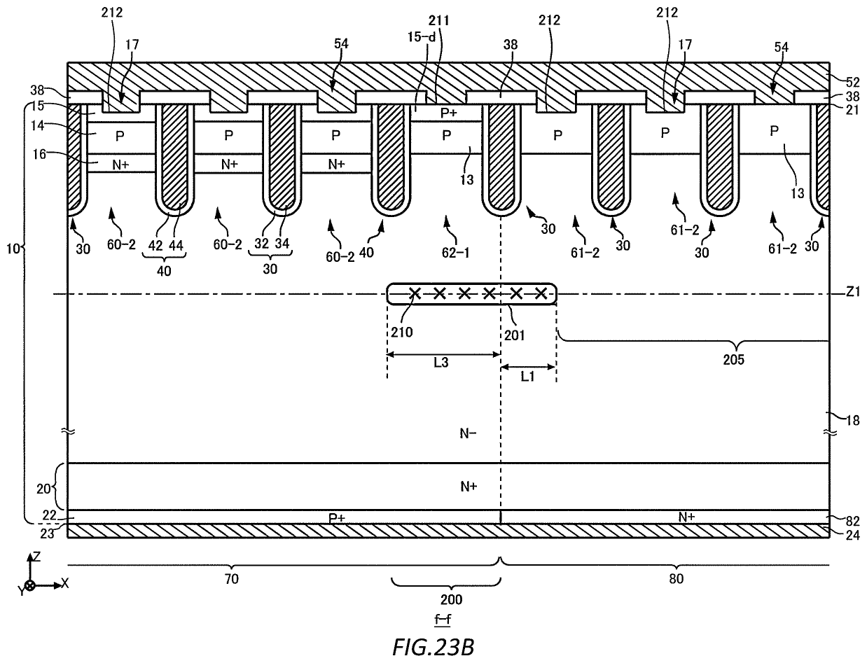

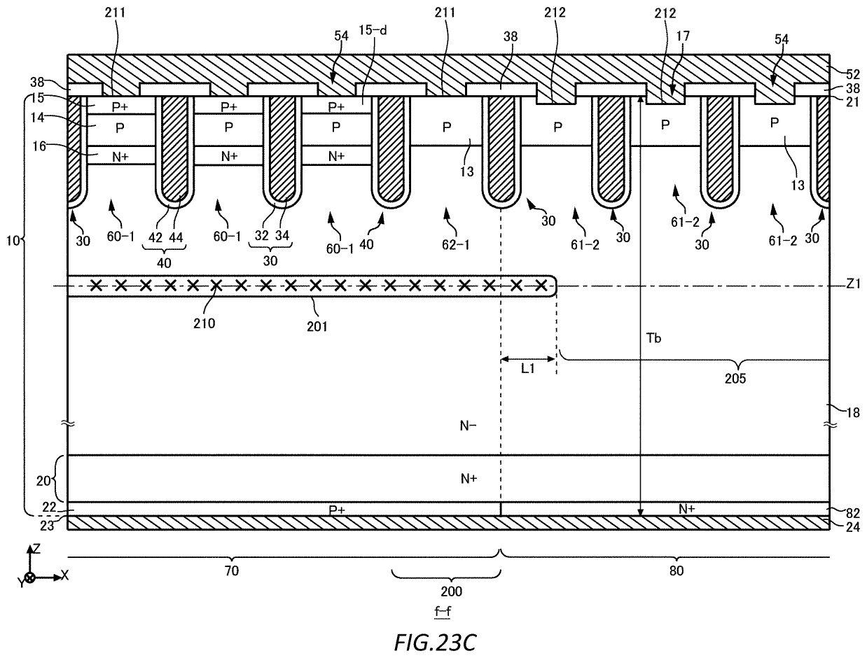

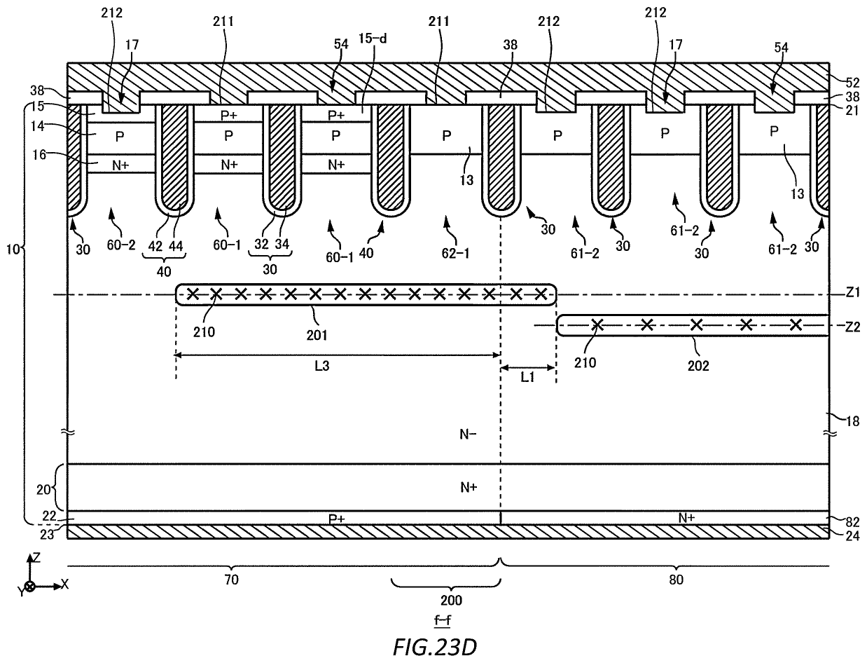

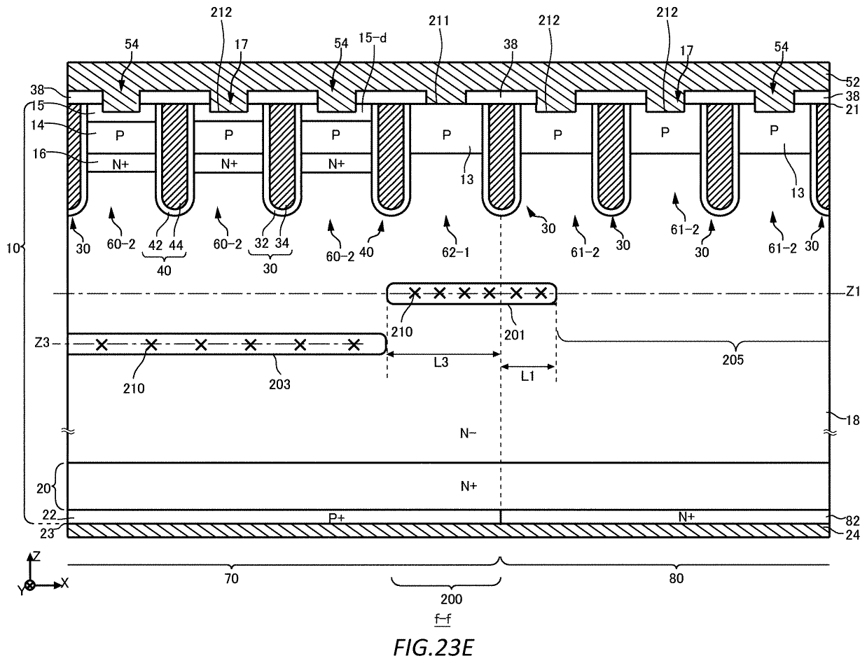

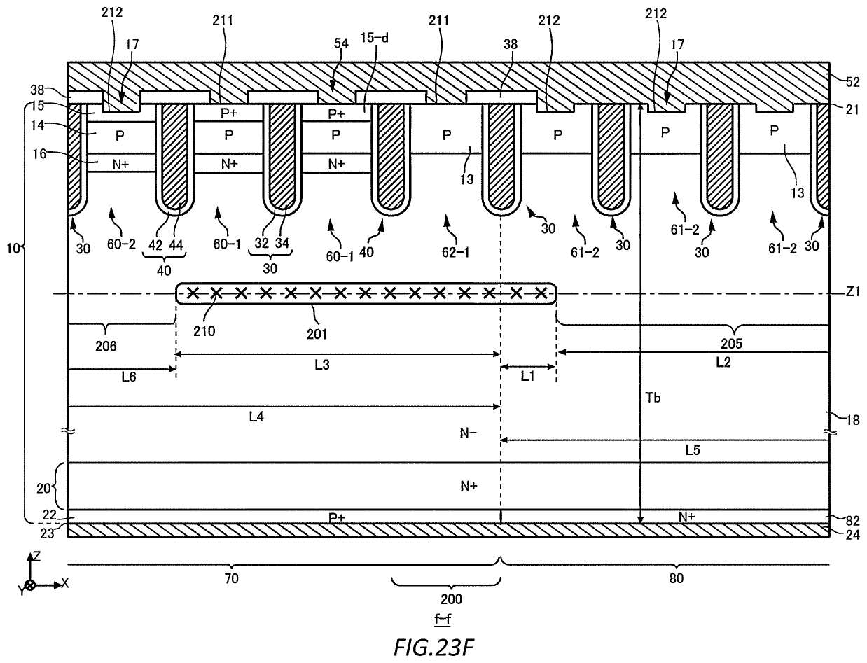

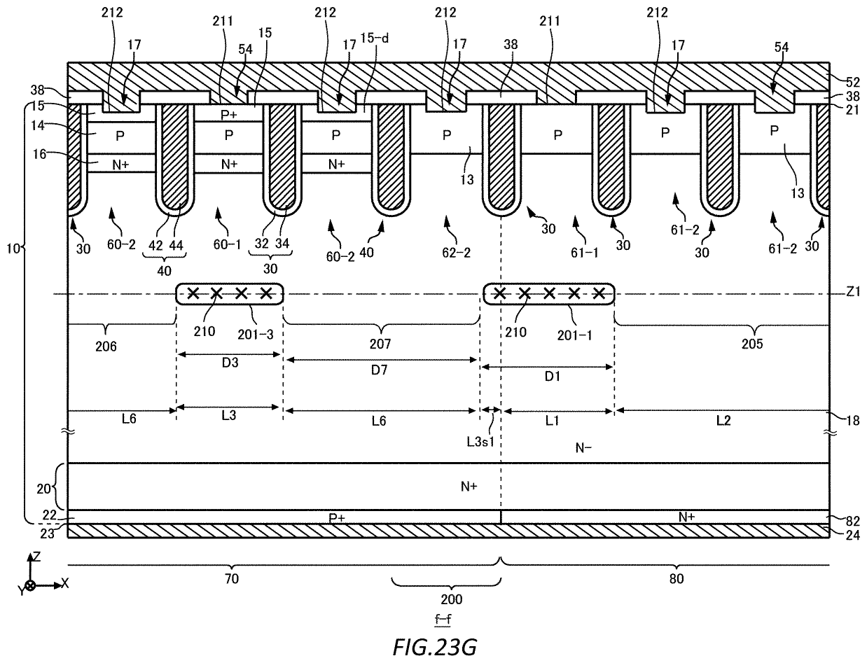

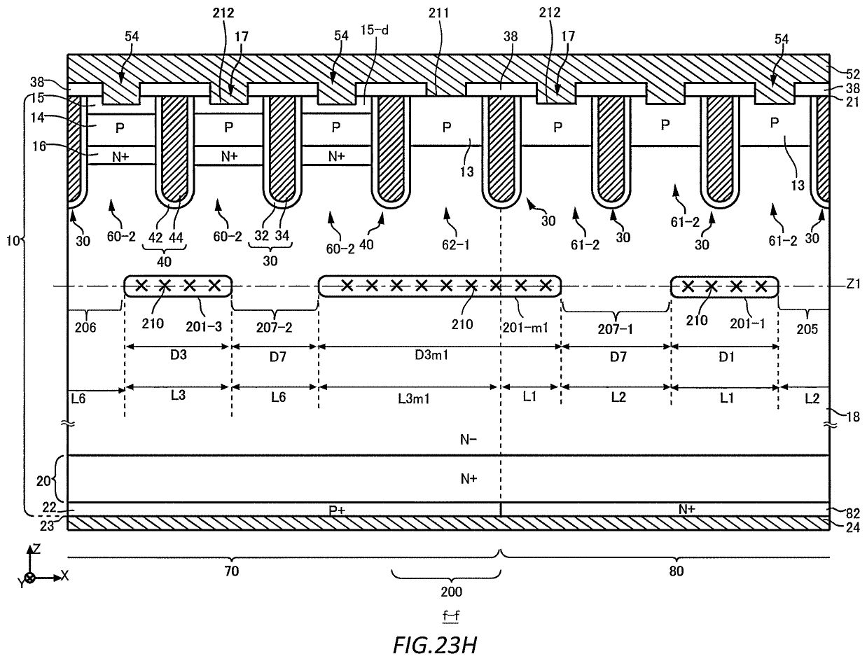

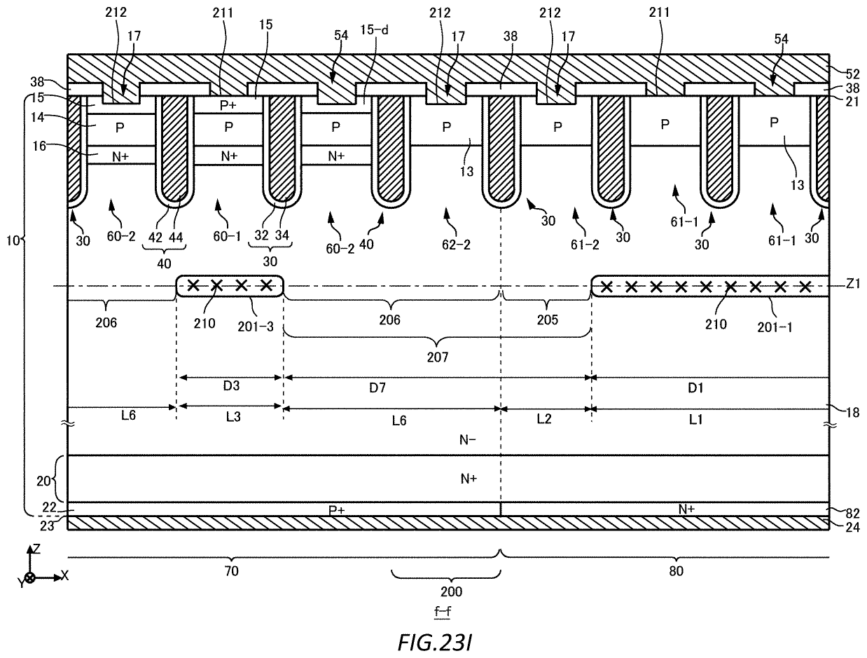

FIG. 23A illustrates a view showing another example of the cross section f-f in FIG. 2. The first depth position in this example is provided at a position shallower than the second depth position with respect to the upper surface 21 of the semiconductor substrate 10. Other structures are similar to those of the examples described in FIG. 6.

FIG. 23B illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 8.

FIG. 23C illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 9.

FIG. 23D illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 10.

FIG. 23E illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 12.

FIG. 23F illustrates another view showing another example of the mesa portion 61 of the diode portion 80. The first depth position in this example is provided at a position shallower than the second depth position with respect to the upper surface 21 of the semiconductor substrate 10. The width of the trench contact portion 17 of the diode portion 80 of this example in the X axis direction is narrower than the width of the mesa portion, but in a region where the interlayer dielectric film 38 is not provided, the trench contact portion 17 may be provided wide until contacting the dummy dielectric film 32, and the upper surface of the dummy trench portion 30 may be removed similarly to the mesa portion 61. Other structures are similar to those in the example of FIG. 17.

FIG. 23G illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 18.

FIG. 23H illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 20A.

FIG. 23I illustrates a view showing another example of the cross section f-f in FIG. 2. The first depth position in this example is provided at a position shallower than the second depth position with respect to the upper surface 21 of the semiconductor substrate 10. Other structures are similar to those in the example of FIG. 21A.

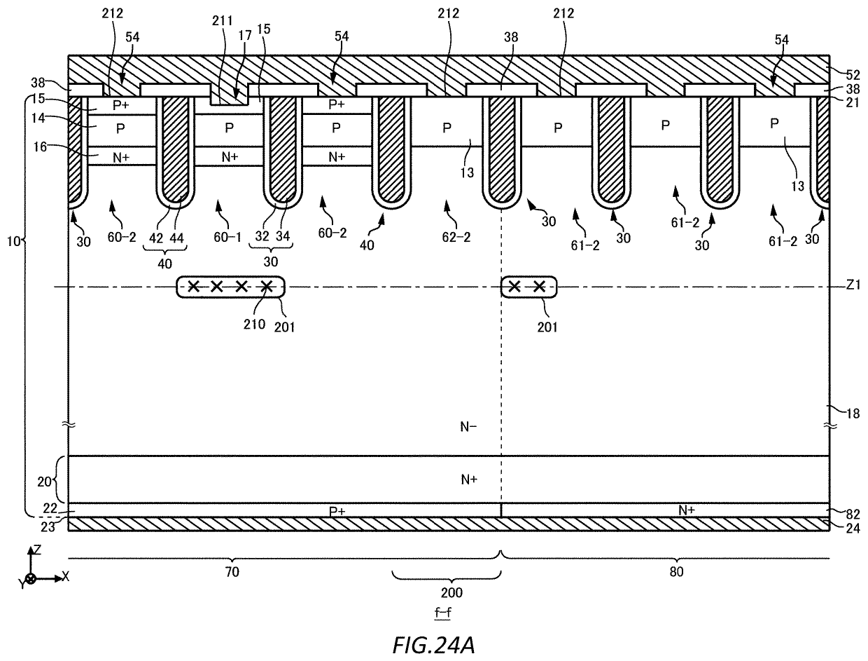

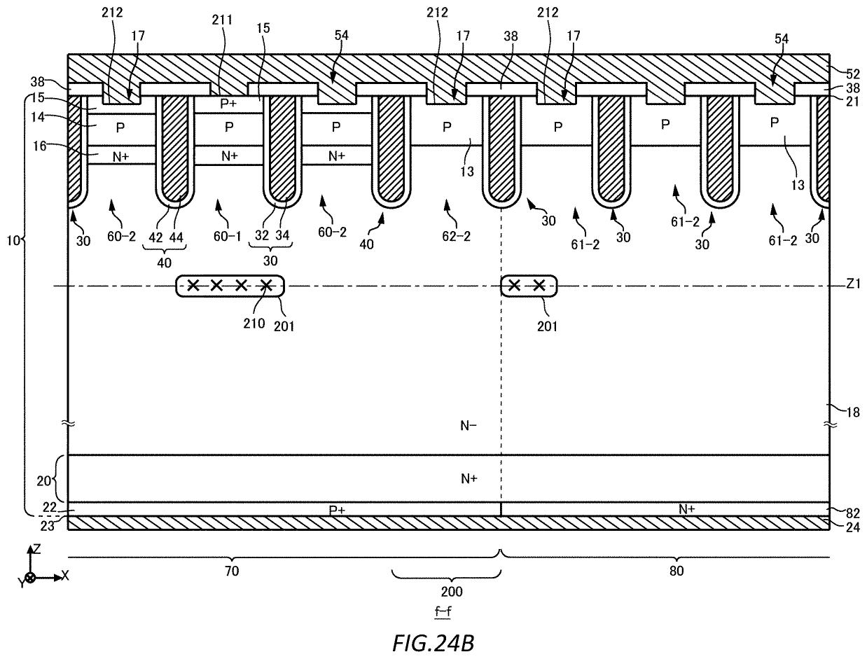

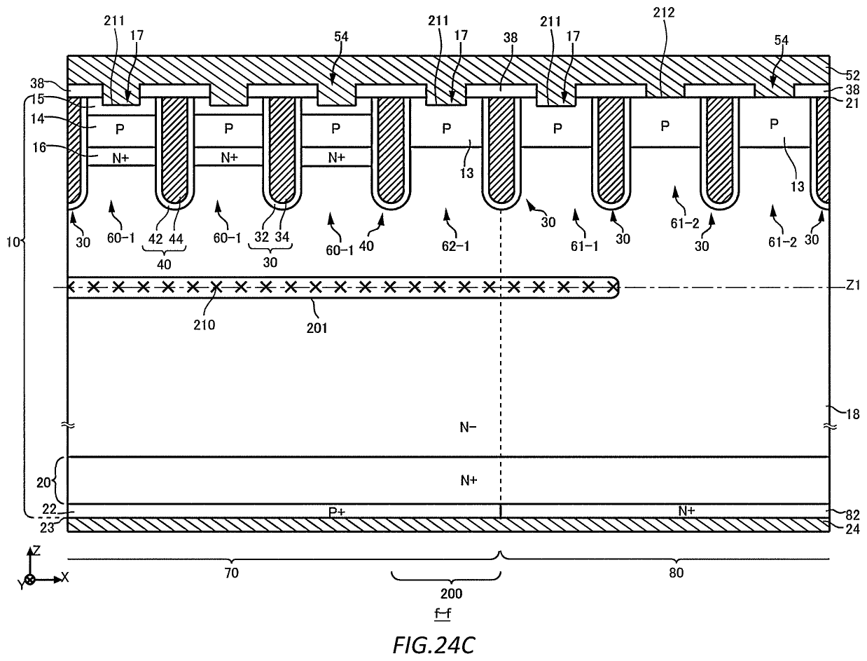

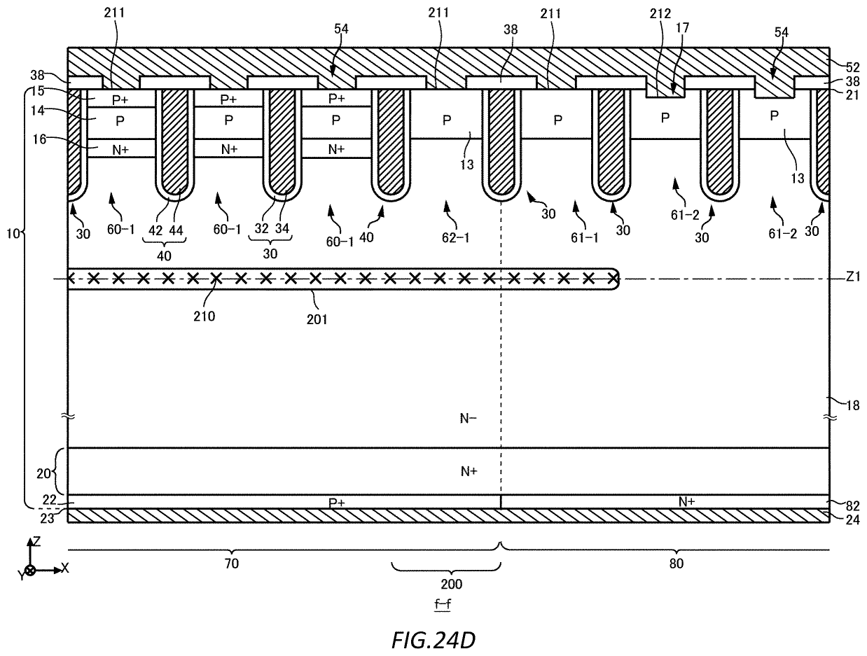

FIG. 24A illustrates a view showing another example of the cross section f-f in FIG. 2. In this example, the first lifetime adjustment region 201 is provided in a portion in contact with the boundary region 200 in the diode portion 80. In addition, the first lifetime adjustment region 201 is provided in a portion away from the boundary region 200 in the transistor portion 70.

In the example of FIG. 24A, the mesa portion 61 in contact with the boundary region 200 in the diode portion 80 partially overlaps the first lifetime adjustment region 201. The mesa portion 61 is defined as the second mesa portion. In another example, the mesa portion having a region overlapping the first lifetime adjustment region 201 in the top view may be defined as the first mesa portion.

In the example of FIG. 24A, the mesa portion 60-1 is the first mesa portion. Although not shown in the example of FIG. 24A, the mesa portion 61-1 and the mesa portion 62-1 are also the first mesa portions. The mesa portion 62-2 of the boundary region 200 is the second mesa portion. In the mesa portion 60 of the transistor portion 70, the mesa portion 60-2 in contact with the boundary region 200 is the second mesa portion. In the example of FIG. 24A, one mesa portion 60 of the transistor portion 70 is the first mesa portion, but a plurality of first mesa portions may be provided in the transistor portion 70. The plurality of first mesa portions may be provided with the trench contact portions 17.

FIG. 24B illustrates a view showing another example of the cross section f-f in FIG. 2. In the example of FIG. 24B, the first depth position is provided at a position shallower than the second depth position with respect to the upper surface 21 of the semiconductor substrate 10. At least one second contact portion 212 includes the trench contact portion 17 in which the emitter electrode 52 is provided inside the semiconductor substrate 10. The second depth position in this example is the depth position of the bottom surface of the trench contact portion 17 provided in the second contact portion 212.

The first depth position in this example is the depth position of the first contact portion 211 provided on the upper surface 21 of the semiconductor substrate 10. The lower end of the first contact portion 211 of this example is arranged on the upper surface 21 of the semiconductor substrate 10. The first contact portion 211 may be a part of the upper surface 21 of the semiconductor substrate 10. In the example of FIG. 24B, the second contact portions 212 of all the second mesa portions are provided with the trench contact portions 17, and the first contact portions 211 of all the first mesa portions are arranged on the upper surface 21. Note that, also in the example of FIG. 24B, any example described in FIG. 24A can be applied for the arrangement of each mesa portion.

FIG. 24C illustrates a view showing another example of the cross section f-f in FIG. 2. In the example of FIG. 24C, the first depth position is provided at a position deeper than the second depth position with respect to the upper surface 21 of the semiconductor substrate 10.

The transistor portion 70 of this example is provided with the first lifetime adjustment region 201 on the entire surface and has the first mesa portion. The diode portion 80 of this example has at least one first mesa portion. In the first mesa portion (mesa portion 61-1) arranged closest to the transistor portion 70 among the first mesa portions of the diode portion 80, the first contact portion 211 may be provided at the first depth position. The mesa portion 61-1 may be provided with the trench contact portion 17. In the diode portion 80 of this example, one or more mesa portions 61 closest to the boundary region 200 are the first mesa portions having the trench contact portions 17.

The diode portion 80 of this example has at least one second mesa portion. The diode portion 80 may have the second mesa portion (mesa portion 61-2) at a position away from the boundary region 200. The first mesa portion (mesa portion 61-1) may be provided between the second mesa portion of the diode portion 80 and the boundary region 200. In at least one second mesa portion among the second mesa portions of the diode portion 80, the second contact portion 212 may be provided at the second depth position. In this example, the second depth position is the position of the upper surface 21.

As shown in FIG. 24C, in the second mesa portion arranged closest to the transistor portion 70 among the second mesa portions of the diode portion 80, the second contact portion 212 may be provided at the second depth position. In all the second mesa portions of the diode portion 80, the second contact portion 212 may be provided at the second depth position.

In the boundary region 200 in this example, all the mesa portions 62 are the first mesa portions. In the transistor portion 70 of this example, one or more mesa portions 60 closest to the boundary region 200 are the first mesa portions. All the mesa portions of the transistor portion 70 may be the first mesa portions. Also in this example, the trench contact portions 17 may be provided in all the first mesa portions. The second contact portions 212 of all the second mesa portions may be arranged on the upper surface 21.

The anode region 13 in the first mesa portion (mesa portion 61-1) of the diode portion 80 may have a doping concentration lower than that of the anode region of the second mesa portion (mesa portion 61-2) by providing the trench contact portion 17. With this configuration, implantation of holes from the mesa portion 61-1 provided with the first lifetime adjustment region 201 is further suppressed.

FIG. 24D illustrates a view showing another example of the cross section f-f in FIG. 2. The example of FIG. 24D is different from the example of FIG. 24 C in that the first depth position is provided at a position shallower than the second depth position. Other structures are similar to those in any example described in FIG. 24C.

The anode region 13 in the second mesa portion (mesa portion 61-2) of the diode portion 80 may have a doping concentration lower than that of the anode region of the first mesa portion (mesa portion 61-1) by providing the trench contact portion 17. With this configuration, implantation of holes from the mesa portion 61-2 not provided with the first lifetime adjustment region 201 can be suppressed.

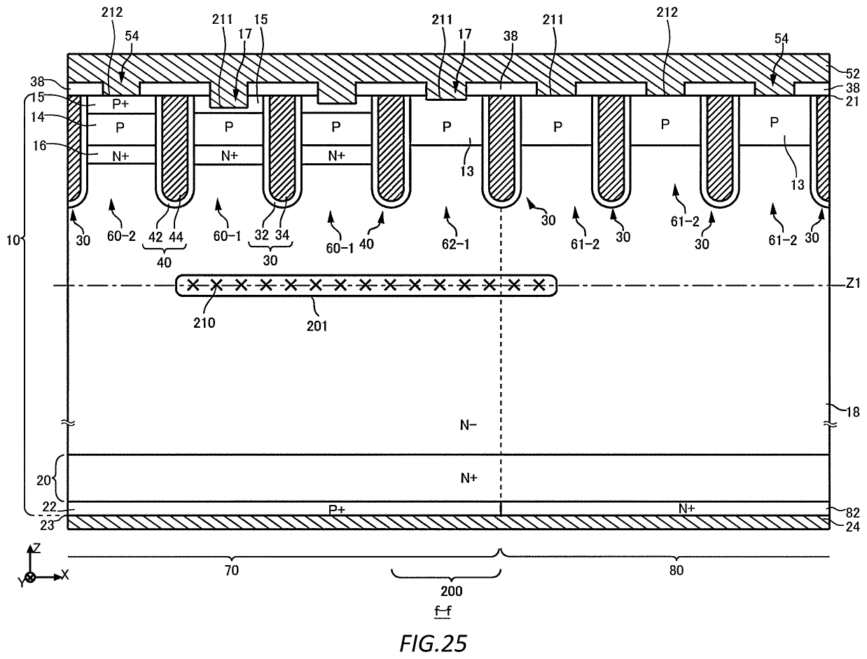

FIG. 25 illustrates a view showing another example of the cross section f-f in FIG. 2. The semiconductor device 100 of this example has a plurality of trench contact portions 17. The plurality of trench contact portions 17 may include a plurality of types of trench contact portions 17 having different lower end depth positions. For example, as a distance from the diode portion 80 increases, the trench contact portion 17 may be formed deeper.

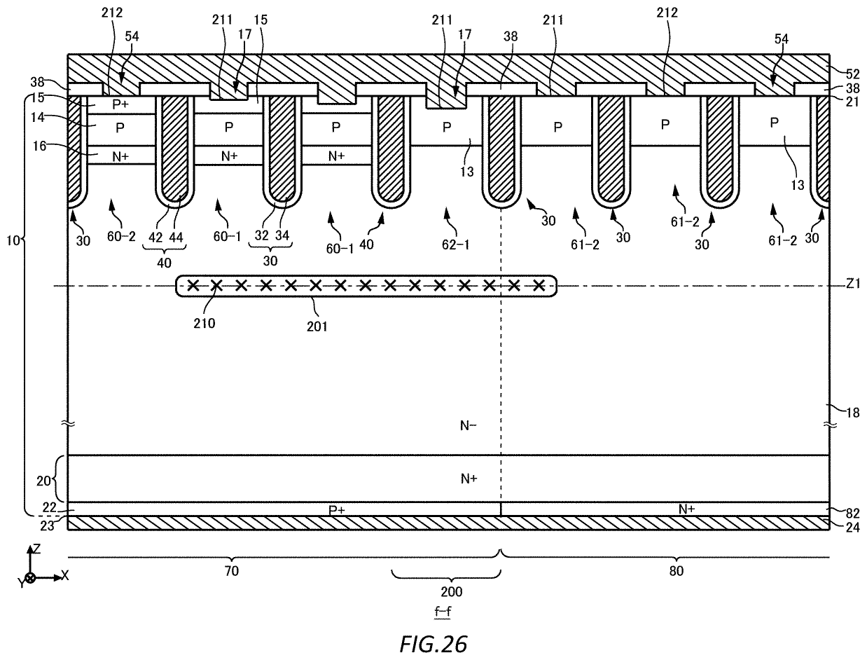

FIG. 26 illustrates a view showing another example of the cross section f-f in FIG. 2. In this example, as the distance from the diode portion 80 increases, the trench contact portion 17 may be formed shallower. However, the arrangement of the depth of the trench contact portion 17 is not limited to the examples of FIGS. 25 and 26. The depth of the trench contact portion 17 provided in the diode portion 80 may be formed deeper or shallower as a distance from the transistor portion 70 increases. The trench contact portions 17 having different depths are not limited to be included in the first contact portion 211, but the trench contact portions 17 having different depths may be included in the second contact portion 212, or the trench contact portions 17 having different depths may be included in each of the first contact portion 211 and the second contact portion 212.

In the above example, an example has been described in which the contact hole 54 and the mesa portion 60 include the first plug region 221, the second plug region 222, the barrier metal 252, and the plug electrode 251, but even when some or all of these are not provided, the withstand capability and characteristics can be adjusted by varying the depth positions of the first contact portion 211 and the second contact portion 212 or by changing the concentration of the P type region of the mesa portion 60 to make a change in implantation of holes.

In the above example, similarly to the transistor portion 70, also in the diode portion 80, the depth of the contact portion of the upper mesa portion is changed according to the presence or absence of the first lifetime adjustment region 201, but the adjustment pattern of the depth of the contact portion may be changed between the transistor portion 70 and the diode portion 80. For example, in the examples described using FIGS. 3A to 24B, in the diode portion 80, the depths of the first contact portion 211 and the second contact portion 212 may not be changed, or adjustment different from that of the transistor portion 70 may be performed. Also in this case, by varying the concentrations and positions of the contact region 15 of the transistor portion 70, the first plug region 221, and the second plug region 222, it is possible to adjust implantation of holes from the transistor portion 70 and the threshold, and it is possible to adjust the withstand capability and the characteristics. On the other hand, also in the example in which the depths of the first contact portion 211 and the second contact portion 212 are changed in the diode portion 80 as shown in FIGS. 18, 21A, 23G, 23I, 24C, and 24D, adjustment different from that of the diode portion 80 may be performed in the transistor portion 70.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

Note that the operations, procedures, steps, and stages of each process performed by an device, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device which includes a semiconductor substrate having an upper surface and a lower surface, the semiconductor device comprising:
a transistor portion which is provided on the semiconductor substrate;
a diode portion which is provided in the semiconductor substrate side by side with the transistor portion in a first direction;
a first lifetime adjustment region which is provided at a first depth on an upper surface side of the semiconductor substrate, has a density of lattice defects that is a first defect density, and includes a region provided in at least one of the transistor portion or the diode portion;
an upper electrode which is provided above the upper surface of the semiconductor substrate;
a plurality of trench portions which are provided from the upper surface to an inside of the semiconductor substrate and arranged side by side in the first direction; and
one or more mesa portions, each of which is arranged between corresponding two of the plurality of trench portions in the first direction and is in contact with the upper electrode, wherein the one or more mesa portions include:
one or more first mesa portions, each of which is provided with the first lifetime adjustment region and has a first contact portion in contact with the upper electrode; and
one or more second mesa portions, each of which is not provided with the first lifetime adjustment region or is provided with a region having a density of the lattice defects lower than that of the first lifetime adjustment region and has a second contact portion in contact with the upper electrode, and
a first depth position of the first contact portion of at least one of the one or more first mesa portions is different from a second depth position of the second contact portion of at least one of the one or more second mesa portions.

2. The semiconductor device according to claim 1, wherein
the first depth position is provided at a position deeper than the second depth position with respect to the upper surface of the semiconductor substrate.

3. The semiconductor device according to claim 1, wherein
the first depth position is provided at a position shallower than the second depth position with respect to the upper surface of the semiconductor substrate.

4. The semiconductor device according to claim 1, wherein
the first contact portion of each of a plurality of the one or more first mesa portions is provided at the first depth position.

5. The semiconductor device according to claim 1, wherein
the first contact portion of each of all of the one or more first mesa portions is provided at the first depth position.

6. The semiconductor device according to claim 1, wherein
the transistor portion has at least one of the one or more first mesa portions, and
in one of the one or more first mesa portions of the transistor portion that is arranged closest to the diode portion, the first contact portion is provided at the first depth position.

7. The semiconductor device according to claim 6, wherein
the diode portion has at least one of the one or more first mesa portions, and
in one of the one or more first mesa portions of the diode portion that is arranged closest to the transistor portion, the first contact portion is provided at the first depth position.

8. The semiconductor device according to claim 7, wherein
the diode portion has at least one of the one or more second mesa portions, and
in the at least one of the one or more second mesa portions of the diode portion, the second contact portion is provided at the second depth position.

9. The semiconductor device according to claim 8, wherein
in one of the one or more second mesa portions of the diode portion that is arranged closest to the transistor portion, the second contact portion is provided at the second depth position.

10. The semiconductor device according to claim 1, wherein
all of the one or more mesa portions in which a contact portion in contact with the upper electrode is provided at the first depth position are each corresponding one of the one or more first mesa portions.

11. The semiconductor device according to claim 2, wherein
the first contact portion includes a trench contact portion in which the upper electrode is provided inside the semiconductor substrate.

12. The semiconductor device according to claim 11, wherein
a lower end of the second contact portion is arranged on the upper surface of the semiconductor substrate.

13. The semiconductor device according to claim 3, wherein
the second contact portion includes a trench contact portion in which the upper electrode is provided inside the semiconductor substrate.

14. The semiconductor device according to claim 13, wherein
a lower end of the first contact portion is arranged on the upper surface of the semiconductor substrate.

15. The semiconductor device according to claim 2, wherein
each of the one or more first mesa portions has:
an emitter region of a first conductivity type exposed on the upper surface of the semiconductor substrate;
a contact region of a second conductivity type exposed on the upper surface of the semiconductor substrate; and
a first plug region of the second conductivity type provided in contact with a lower end of the first contact portion and having a doping concentration higher than that of the contact region.

16. The semiconductor device according to claim 3, wherein
each of the one or more second mesa portion has:
an emitter region of a first conductivity type exposed on the upper surface of the semiconductor substrate;
a contact region of a second conductivity type exposed on the upper surface of the semiconductor substrate; and
a second plug region of the second conductivity type provided in contact with a lower end of the second contact portion and having a doping concentration higher than that of the contact region.

17. The semiconductor device according to claim 1, wherein
a first length in the first direction by which the first lifetime adjustment region is provided in the diode portion is 0, or is smaller than a second length in the first direction by which the first lifetime adjustment region is not provided in the diode portion.

18. The semiconductor device according to claim 1, wherein
a first length in the first direction by which the first lifetime adjustment region is provided in the diode portion is 0, or is smaller than a total value of third lengths, in the first direction, of first lifetime adjustment regions, each being identical to the first lifetime adjustment region, provided in the transistor portion.

19. The semiconductor device according to claim 1, wherein
the diode portion has a plurality of mesa portions, each of which is identical to corresponding one of the one or more mesa portions and is arranged between corresponding two of the plurality of trench portions in the first direction, and
the diode portion has, below at least two of the plurality of mesa portions arranged adjacent to each other in the first direction, a region in which the first lifetime adjustment region is not provided.

20. The semiconductor device according to claim 1, wherein
the first lifetime adjustment region is provided in both of the transistor portion and the diode portion, and
the first lifetime adjustment region of the transistor portion and the first lifetime adjustment region of the diode portion are separated from each other.
